(19) United States
(12) Patent Application Publication
(10) Pub. No.: US 2024/0250697 A1
(43) Pub. Date: Jul. 25, 2024

(54) ENCODING METHOD, DECODING METHOD, AND COMMUNICATION APPARATUS

(71) Applicant: HUAWEI TECHNOLOGIES CO., LTD., Shenzhen (CN)

(72) Inventors: Xianbin WANG, Hangzhou (CN); Huazi ZHANG, Hangzhou (CN); Jiajie TONG, Hangzhou (CN); Rong LI, Boulogne Billancourt (FR); Jun WANG, Hangzhou (CN)

(21) Appl. No.: 18/585,501

(22) Filed: Feb. 23, 2024

Related U.S. Application Data
(63) Continuation of application No. PCT/CN2022/112907, filed on Aug. 17, 2022.

(30) Foreign Application Priority Data
Aug. 24, 2021 (CN) 202110971999.4

(51) Int. Cl. H03M 13/13; H03M 13/09

(52) U.S. Cl. CPC H03M 13/13; H03M 13/09

(57) ABSTRACT

An encoding method, a decoding method, and a communication apparatus. The communication apparatus obtains an information bit sequence with a length K. A length K1 of a first sequence based on K or M is determined, where M is a quantity of modulation symbols. A first vector is obtained based on K, K1, and a predefined sequence. A length of the first vector is 2JM, J is a modulation order, the first vector indicates J coding sub-blocks, the J coding sub-blocks separately belong to a first-type sub-block including at least one coding sub-block or a second-type sub-block including at least one coding sub-block. The communication apparatus determines frozen bit locations in the first-type sub-block and information bit locations in the second-type sub-block and encodes the information bit sequence based on the frozen bit locations in the first-type sub-block, the information bit locations in the second-type sub-block, and the first vector.

### CROSS-REFERENCE TO RELATED APPLICATIONS

This application is a continuation of International Patent Application No. PCT/CN2022/112907, filed on Aug. 17, 2022, which claims priority to Chinese Patent Application No. 202110971999.4, filed on Aug. 24, 2021. The disclosures of the aforementioned applications are hereby incorporated by reference in their entireties.

### BACKGROUND

In recent years, as a polar code is included in a 5th generation (5G) wireless communication standard, design of a polar code modulation scheme also becomes a hot topic in communication research. In a higher-order modulation technology, a plurality of codeword bits are mapped to a same modulation symbol to improve spectral efficiency. In higher-order modulation, different modulation symbols correspond to different energy. Sending more low-energy modulation symbols and less high-energy modulation symbols saves average energy. For a white Gaussian noise channel, in response to distribution of transmitted modulation symbols complying with Gaussian distribution, an amount of information transmitted per unit energy is the largest.

To make transmitted modulation symbols conform to Gaussian distribution, a probabilistic shaping technology is introduced. Currently, in an online construction algorithm that is based on density evolution, reliability of each sub-channel is to be calculated on line. Implementation complexity is high. In addition, there is a polar-based offline construction method, to be specific, based on a given sequence, information bits and frozen bits are sequentially read from the sequence. However, this method cannot adapt to a usage of polar code construction in which probabilistic shaping is introduced.

### SUMMARY

Embodiments described herein provide an encoding method, a decoding method, and a communication apparatus, to improve coding efficiency.

According to a first aspect, at least one embodiment provides an encoding method and a decoding method. The encoding method is performed by a sending apparatus, and the decoding method is performed by a receiving apparatus. The sending apparatus is user equipment (UE), a vehicle-mounted device, a terminal device, a module (for example, a chip) in the terminal device, or the like. The sending apparatus is alternatively a transmission reception point (TRP), a 5G base station (gNodeB, gNB), a network device, a module (for example, a chip) in the network device, or the like. The receiving apparatus is the same as the foregoing sending apparatus. Details are not described herein. However, the sending apparatus and the receiving apparatus are different communication apparatuses. For example, the sending apparatus is a terminal device, and the receiving apparatus is a network device. This is not limited in at least one embodiment.

The sending apparatus obtains an information bit sequence, where a length of the information bit sequence is K; and determine a length K1 of a first sequence based on K or M, where M is a quantity of modulation symbols, and K, K1, and M are positive integers. The sending apparatus obtains a first vector based on K, K1, and a predefined sequence, where a length of the first vector is 2JM, M is the quantity of modulation symbols, J is a modulation order, M and J are positive integers, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block; determine frozen bit locations in the first-type sub-block and information bit locations in the second-type sub-block; and encode the information bit sequence based on the frozen bit locations in the first-type sub-block, the information bit locations in the second-type sub-block, and the first vector.

Correspondingly, in response to the receiving apparatus performing the decoding method, the receiving apparatus obtains a to-be-decoded sequence (the to-be-decoded sequence is understood as a scrambled encoded sequence because interference or the like exists in response to an encoded sequence obtained through encoding by the sending apparatus being transmitted on a channel between the sending apparatus and the receiving apparatus): determine K and M (values of K and M is obtained by using indication signaling, where the indication signaling is uplink control information (UCI), downlink control information (DCI), or the like, or is agreed upon with the sending apparatus in advance, and is not limited herein), where K is a length of an information bit sequence, and M is a quantity of modulation symbols: determine K1 based on K or M, where K, K1, and M are positive integers; obtain a first vector based on K, K1, and a predefined sequence, where a length of the first vector is 2JM, J is a modulation order, J is a positive integer, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block; determine frozen bit locations in the first-type sub-block and information bit locations in the second-type sub-block; and decode the to-be-decoded sequence based on the frozen bit locations in the first-type sub-block, the information bit locations in the second-type sub-block, and the first vector, to obtain the information bit sequence whose length is K.

The encoding method provided in at least one embodiment is applied to higher-order modulation, for example, 64 quadrature amplitude modulation (QAM), 256QAM, or 1024QAM. The information bit sequence is understood as a sequence that uses coding processing, or is understood as a to-be-encoded sequence. An information bit sequence length (that is, an information bit quantity) is determined, and the length of the information bit sequence is K. To improve robustness and reduce complexity during encoding, the information bit sequence is divided into the first sequence and a second sequence, and different coding processing is performed for different sequences. In actual application, in response to shaping being introduced during encoding, the first sequence is understood as a sequence for shaping. Certainly, in actual application, another encoding operation (an operation different from conventional polar coding) is introduced, and the first sequence is a sequence for another encoding operation. This is not limited in at least one embodiment.

In addition, the predefined sequence is understood as a sequence that meets a mother code length (a sequence length meets 2^{N}, where N is a positive integer), for example, a sequence whose length is 8: [1, 2, 3, 5, 4, 6, 7, 8]: or is understood as another sequence, for example, a sequence pre-agreed upon by the sending apparatus and the receiving apparatus. This is not limited in at least one embodiment.

In response to an encoding operation being performed, a modulation scheme (for example, the modulation scheme is 64QAM higher-order modulation), the modulation order J being 3 (r=log₂(\sqrt{64})=3), and the quantity M of modulation symbols (the quantity of modulation symbols is preset, for example, agreed upon by the sending apparatus and the receiving apparatus) is to be determined, to construct the first vector whose length is 2JM based on K, K1, the predefined sequence, the modulation order, and the quantity of modulation symbols. A location of the information bit sequence corresponding to the first vector is determined based on the first vector (for example, in response to the information bit sequence being [0 1 0], and the first vector is [0 0 0 0 0 1 1 1], the information bit sequence corresponds to 111 in the first vector. In this case, in response to an encoding operation being performed, the 6th, the 7th, and the 8th locations are set as information bit locations, and other locations are set as frozen bit locations). In addition, the information bit locations and the frozen bit locations are determined by using the first vector, and an encoding operation is efficiently performed based on the obtained frozen bit locations and the obtained information bit locations.

In addition, the first vector indicates the J coding sub-blocks, the J coding sub-blocks separately belong to the first-type sub-block or the second-type sub-block, the first-type sub-block includes at least one coding sub-block, and the second-type sub-block includes at least one coding sub-block. Because another encoding operation such as a shaping operation is introduced during encoding, the first-type sub-block is understood as a shaping sub-block. To ensure that a decoder, that is, the receiving apparatus, more quickly obtains the information bit sequence through decoding in response to another encoding operation being introduced, the information bit sequence is encoded based on the frozen bit locations in the first-type sub-block, the information bit locations in the second-type frozen bit, and the first vector, to improve decoding efficiency of the decoder.

In response to an encoding operation being performed in at least one embodiment, a solution (that is, online coding) of adjusting a coding policy based on a channel status is not used. Instead, the first vector is constructed based on the length of the information bit sequence, the length of the first sequence, and the predefined sequence, different coding sub-blocks are indicated based on the first vector, and the information bit sequence is encoded based on information bit locations and frozen bit locations in the different coding sub-blocks and the first vector. In this way, encoding efficiency is improved, and calculation complexity is reduced compared with online coding.

In an optional implementation, the sending apparatus or the receiving apparatus determines a first index set Θ based on K, K1, and the predefined sequence, and obtain the first vector based on the first index set Θ, where a location index i in the first vector satisfies:
if i∈Θ, the location index i carries a first preset value; and
if i∉Θ, the location index i carries a second preset value, where the first preset value is different from the second preset value, 1≤i≤2JM, and i is a positive integer.

After the first index set is determined based on K, K1, and the predefined sequence, the first vector is obtained based on the first index set. In this way, information bit locations and check bit locations are directly obtained, thereby reducing coding construction complexity.

In an optional implementation, the first preset value is 1, and the second preset value is 0; or the first preset value is 0, and the second preset value is 1. This is not limited herein in at least one embodiment. Usually, the first preset value indicates a location of the information bit sequence.

In an optional implementation, an element carried at a (2M(y−1)+1)th location in the first vector to an element carried at a (2My)^{th} location in the first vector correspond to a y^{th} coding sub-block, 1≤y≤J, and y is a positive integer. In other words, lengths of the coding sub-blocks indicated by the first vector are all 2M.

In an optional implementation, the sending apparatus selects F information bit locations from the information bit locations in the second-type sub-block, where F is a length of frozen bits in the first-type sub-block, and F is an integer; and assign values of the F frozen bit locations in the first-type sub-block to the F information bit locations in the second-type sub-block.

Assigning the values of the F frozen bit locations in the first-type sub-block to the F information bit locations in the second-type sub-block is understood as directly duplicating the values of the F frozen bit locations in the first-type sub-block to the information bit locations in the second-type sub-block, or is understood as assigning the values of the F frozen bit locations in the first-type sub-block to the information bit locations in the second-type sub-block through encoding (scrambling, exclusive OR, or the like). In actual application, a value assignment manner is not limited in at least one embodiment.

In addition, in actual application, the length of the frozen bits in the first-type sub-block is alternatively F1 (if a length of all frozen bits in the first-type sub-block is 5, F1 is 3 or another value less than 5), and F2 information bit locations is selected from the information bit locations in the second-type sub-block. A value of F2 is different from that of F1. This is not limited herein in at least one embodiment, provided that a relationship between the frozen bits of the first-type sub-block and information bits of the second-type sub-block is determined. The relationship between the frozen bits of the first-type sub-block and the information bits of the second-type sub-block is determined, to help the receiving apparatus perform decoding more quickly.

In an optional implementation, the sending apparatus performs shaping mapping and polar transform on the first sequence to obtain a third sequence: extract a fourth sequence from the third sequence based on the first vector, where an element in the fourth sequence is a value of an information bit location in the first-type sub-block, and a length of the fourth sequence is less than a length of the third sequence; perform cyclic redundancy check (CRC) calculation on a fifth sequence to obtain a sixth sequence, where the fifth sequence includes a second sequence and the fourth sequence; and encode the sixth sequence.

Decoding performance is improved by introducing CRC.

In an optional implementation, the sending apparatus or the receiving apparatus determines K1 in the following manner:
manner 1: determining K1 based on an index value corresponding to K or M: or
manner 2:
determining K1 by using the following formula:

$$K 1 = ⌊ {log}_{2} {C}_{2 M}^{⌊ 2 {Mp}_{b i a s} ⌋} ⌋ ,$$

where
K1 represents a length of a first sequence, M represents the quantity of modulation symbols, and p_{bias} represents a preset shaping probability.

Determining K1 in the manner 1 is simpler, and has a smaller calculation amount. In the manner 2, K1 is determined based on the quantity of modulation symbols and the preset shaping probability. Compared with the manner 1, in the manner 2, a calculation amount is increased, but reliability is higher and flexibility is higher.

In an optional implementation, the sending apparatus or the receiving apparatus determines a first parameter T based on K and K1, and select T sequence elements from the predefined sequence to construct the first index set Θ.

In this implementation, information bit locations and check bit locations are directly obtained, thereby reducing coding construction complexity.

In an optional implementation, the sending apparatus or the receiving apparatus determines T in the following manner:
manner 1:

$$T = 2 M + K - K 1 ,$$

where
T′ represents the first parameter, M represents the quantity of modulation symbols, K represents the length of the information bit sequence, and K1 represents the length of the first sequence: or
manner 2:
the first parameter is further related to a CRC length, and T is determined by using the following formula:

$$T = 2 M + K + L - K 1 ,$$

where
T represents the first parameter, M represents the quantity of modulation symbols, K represents the length of the information bit sequence, K1 represents the length of the first sequence, and L represents the CRC length.

In addition, the first sequence is a plurality of bits, and there is also a plurality of first-type sub-blocks. Assuming that the first sequence is q sub-sequences, in response to the first parameter being related to the CRC length, the first parameter is determined by referring to the following formula:

$$T = 2 q M + K + L - {\sum }_{x = 1}^{q} {K}_{x , 1} ,$$

where
T represents the first parameter, M represents the quantity of modulation symbols, K represents the length of the information bit sequence, q represents a quantity of sub-sequences of the first sequence, K1 represents the length of the first sequence, L represents the CRC length, and K_{x,1} represents a length of an x^{th} sub-sequence.

In an optional implementation, the sending apparatus or the receiving apparatus selects T sequence elements from the predefined sequence as the first index set according to a first rule, where the first rule includes one of the following: selecting T sequence elements forward from the last sequence element of the predefined sequence as the first index set, and selecting T sequence elements backward from the 1^{st} sequence element of the predefined sequence as the first index set.

According to a second aspect, at least one embodiment provides a communication apparatus. The communication apparatus is understood as the foregoing sending apparatus, and includes an input/output unit and a processing unit.

The input/output unit is configured to obtain an information bit sequence, where a length of the information bit sequence is K, and K is a positive integer. The processing unit is configured to: determine a length K1 of a first sequence based on K or M, where M is a quantity of modulation symbols, and K1 and M are positive integers: obtain a first vector based on K, K1, and a predefined sequence, where a length of the first vector is 2JM, M is the quantity of modulation symbols, J is a modulation order, M and J are positive integers, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block: determine frozen bit locations in the first-type sub-block and information bit locations in the second-type sub-block; and encode the information bit sequence based on the frozen bit locations in the first-type sub-block, the information bit locations in the second-type sub-block, and the first vector.

In an optional implementation, the processing unit is configured to:

determine a first index set Θ (based on K, K1, and the predefined sequence; and obtain the first vector based on the first index set Θ, where a location index i in the first vector satisfies: in response to i∈Θ, the location index i carries a first preset value; and in response to i∉Θ, the location index i carries a second preset value, where the first preset value is different from the second preset value, 1≤i≤2JM, and i is a positive integer.

In an optional implementation, an element carried at a (2M(y−1)+1)th location in the first vector to an element carried at a (2My)^{th} location in the first vector correspond to a y^{th} coding sub-block, 1≤y≤J, and y is a positive integer.

In an optional implementation, the processing unit is further configured to: select F information bit locations from the information bit locations in the second-type sub-block, where F is a length of frozen bits in the first-type sub-block, and F is an integer; and assign values of the F frozen bit locations in the first-type sub-block to the F information bit locations in the second-type sub-block.

In an optional implementation, the processing unit is further configured to: perform shaping mapping and polar transform on the first sequence to obtain a third sequence; extract a fourth sequence from the third sequence based on the first vector, where an element in the fourth sequence is a value of an information bit location in the first-type sub-block, and a length of the fourth sequence is less than a length of the third sequence; perform cyclic redundancy check CRC calculation on a fifth sequence to obtain a sixth sequence, where the fifth sequence includes a second sequence and the fourth sequence; and encode the sixth sequence and the second sequence.

In an optional implementation, K1 is determined in the following manner:
manner 1: determining K1 based on an index value corresponding to K or M; or
manner 2:
determining K1 by using the following formula:

$$K 1 = ⌊ {log}_{2} {C}_{2 M}^{⌊ 2 {Mp}_{b i a s} ⌋} ⌋ ,$$

where
K1 represents a length of a first sequence, M represents the quantity of modulation symbols, and p_{bias} represents a preset shaping probability.

In an optional implementation, the processing unit is configured to: determine a first parameter T based on K and K1, and select T sequence elements from the predefined sequence to construct the first index set Θ.

In an optional implementation, T is determined in the following manner:
manner 1:

$$T = 2 M + K - K 1 ,$$

where
T represents the first parameter, M represents the quantity of modulation symbols, K represents the length of the information bit sequence, and K1 represents the length of the first sequence; or
manner 2:
the first parameter is further related to a CRC length, and T is determined by using the following formula:

$$T = 2 M + K + L - K 1 ,$$

where
T represents the first parameter, M represents the quantity of modulation symbols, K represents the length of the information bit sequence, K1 represents the length of the first sequence, and L represents the CRC length.

In an optional implementation, the processing unit is configured to:
select T sequence elements from the predefined sequence as the first index set according to a first rule, where the first rule includes one of the following: selecting T sequence elements forward from the last sequence element of the predefined sequence as the first index set, and selecting T sequence elements backward from the 1^{st} sequence element of the predefined sequence as the first index set.

In an optional implementation, the first preset value is 1, and the second preset value is 0; or the first preset value is 0, and the second preset value is 1.

According to a third aspect, at least one embodiment provides a communication apparatus. The communication apparatus is understood as a receiving apparatus, and includes an input/output unit and a processing unit.

The input/output unit is configured to: obtain a to-be-decoded sequence; and determine K and M, where K is a length of an information bit sequence, and M is a quantity of modulation symbols. The processing unit is configured to: determine K1 based on K or M, where K, K1, and M are positive integers; obtain a first vector based on K, K1, and a predefined sequence, where a length of the first vector is 2JM, J is a modulation order, J is a positive integer, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block; determine frozen bit locations in the first-type sub-block and information bit locations in the second-type sub-block; and decode the to-be-decoded sequence based on the frozen bit locations in the first-type sub-block, the information bit locations in the second-type sub-block, and the first vector, to obtain the information bit sequence whose length is K.

In an optional implementation, the processing unit is configured to: determine a first index set Θ based on K, K1, and the predefined sequence, and obtain the first vector based on the first index set Θ, where a location index i in the first vector satisfies:

if i∈Θ, the location index i carries a first preset value; and

if i∉Θ, the location index i carries a second preset value, where the first preset value is different from the second preset value, 1≤i≤2JM, and i is a positive integer.

In an optional implementation, an element carried at a (2M(y−1)+1)^{th} location in the first vector to an element carried at a (2My)^{th} location in the first vector correspond to a y^{th} coding sub-block, 1≤y≤J, and y is a positive integer.

In an optional implementation, the processing unit is further configured to: select F information bit locations from the information bit locations in the second-type sub-block, where F is a length of frozen bits in the first-type sub-block, and F is an integer; and assign values of the F frozen bit locations in the first-type sub-block to the F information bit locations in the second-type sub-block.

In an optional implementation, K1 is determined in the following manner:
manner 1:
determining K1 based on an index value corresponding to K or M; or
manner 2:
determining K1 by using the following formula:

$$K 1 = ⌊ {log}_{2} {C}_{2 M}^{⌊ 2 {Mp}_{b i a s} ⌋} ⌋ ,$$

where
K1 represents a length of the first sequence; M represents a quantity of modulation symbols; and p_{bias} represents a preset shaping probability.

In an optional implementation, the processing unit is configured to: determine a first parameter T based on K and K1, and select T sequence elements from the predefined sequence to construct the first index set Θ.

In an optional implementation, T is determined in the following manner:
manner 1:

$$T = 2 M + K - K 1 ,$$

where
T represents the first parameter, M represents the quantity of modulation symbols, K represents the length of the information bit sequence, and K1 represents the length of the first sequence; or
manner 2:
the first parameter is further related to a CRC length, and T is determined by using the following formula:

$$T = 2 M + K + L - K 1 ,$$

where
T represents the first parameter, M represents the quantity of modulation symbols, K represents the length of the information bit sequence, K1 represents the length of the first sequence, and L represents the CRC length.

In an optional implementation, the processing unit is configured to select T sequence elements from the predefined sequence as the first index set according to a first rule, where the first rule includes one of the following: selecting T sequence elements forward from the last sequence element of the predefined sequence as the first index set, and selecting T sequence elements backward from the 1^{st} sequence element of the predefined sequence as the first index set.

In an optional implementation, the first preset value is 1, and the second preset value is 0; or the first preset value is 0, and the second preset value is 1.

For the second aspect or the third aspect, the input/output unit is referred to as a transceiver unit, a communication unit, or the like. In response to the communication apparatus being a terminal device, the input/output unit is a transceiver, and the processing unit is a processor. In response to the communication apparatus being a module (for example, a chip) in a terminal device, the input/output unit is an input/output interface, an input/output circuit, an input/output pin, or the like, and is also referred to as an interface, a communication interface, an interface circuit, or the like. The processing unit is a processor, a processing circuit, a logic circuit, or the like.

According to a fourth aspect, at least one embodiment provides a communication apparatus, including at least one processor and a memory. The memory is configured to store a computer program or instructions. In response to the apparatus running, the at least one processor executes the computer program or the instructions, so that the communication apparatus performs the method according to the first aspect or the implementations of the first aspect.

According to a fifth aspect, at least one embodiment provides another communication apparatus, including an interface circuit and a logic circuit. The interface circuit is understood as an input/output interface, and the logic circuit is configured to run code instructions to perform the method according to the first aspect or the implementations of the first aspect.

According to a sixth aspect, at least one embodiment further provides a computer-readable storage medium, where the computer-readable storage medium stores computer-readable instructions. In response to the computer-readable instructions being run on a computer, the computer is enabled to perform the method according to any one of the first aspect.

According to a seventh aspect, at least one embodiment further provides a computer program product including instructions. In response to the instructions being run on a computer, the computer performs the method according to the first aspect or the implementations of the first aspect.

According to an eighth aspect, at least one embodiment provides a chip system. The chip system includes a processor, and further includes a memory, configured to implement the method according to any one of the first aspect. The chip system includes a chip, or includes a chip and another discrete component.

According to a ninth aspect, at least one embodiment provides a communication system, where the system includes a sending apparatus and a receiving apparatus. The communication system is configured to perform the method according to any one of the first aspect.

For technical effects that are achieved in the second aspect to the ninth aspect, refer to descriptions of technical effects that are achieved by corresponding embodiments in the first aspect. Details are not described herein again in at least one embodiment.

### BRIEF DESCRIPTION OF DRAWINGS

FIG. 1 is a schematic diagram of a communication system according to at least one embodiment;

FIG. 2 is a schematic diagram of an encoding and decoding procedure according to at least one embodiment;

FIG. 3 is a schematic diagram of polar coding according to at least one embodiment;

FIG. 4 is a schematic flowchart of an encoding and decoding method according to at least one embodiment;

FIG. 5 is a schematic diagram of a CRC execution procedure according to at least one embodiment;

FIG. 6 is a schematic diagram of encoding according to at least one embodiment;

FIG. 7 is a schematic flowchart of performing polar shaping according to at least one embodiment;

FIG. 8 is a schematic diagram of modulation symbol mapping according to at least one embodiment;

FIG. 9 is a comparison diagram showing simulation results;

FIG. 10 is a comparison diagram showing simulation results;

FIG. 11 is a schematic diagram of a structure of a communication apparatus according to at least one embodiment;

FIG. 12 is a schematic diagram of a structure of a communication apparatus according to at least one embodiment; and

FIG. 13 is a schematic diagram of a structure of a communication apparatus according to at least one embodiment.

### DESCRIPTION OF EMBODIMENTS

To make the objectives, technical solutions, and advantages of at least one embodiment clearer, the following further describes at least one embodiment in detail with reference to the accompanying drawings. A specific operation method in a method embodiment is also applied to an apparatus embodiment or a system embodiment. In the descriptions of at least one embodiment, unless otherwise specified, a plurality of means two or more than two. Therefore, for implementation of the apparatus and the method, reference is made to each other, and repeated parts are not described again.

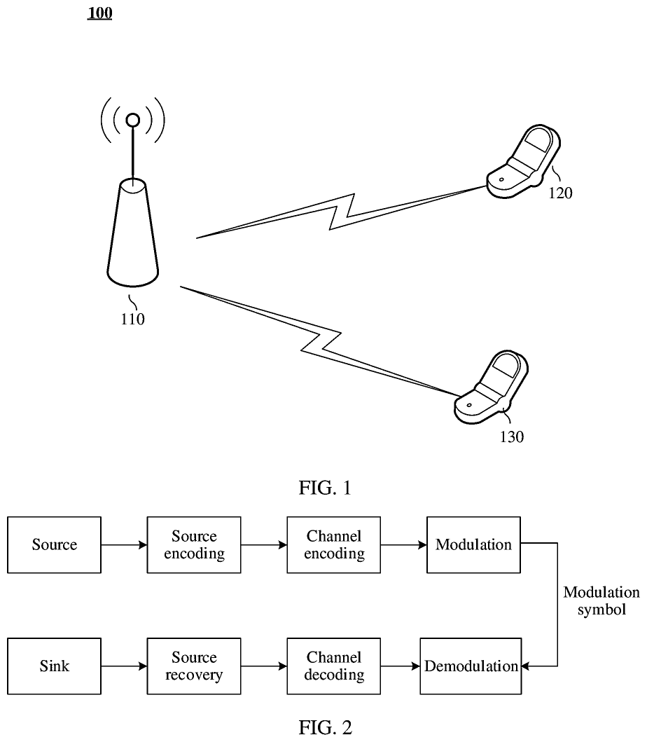

At least one embodiment is applied to a 5G NR system, or is applied to another communication system, for example, a next-generation communication system. As shown in FIG. 1, at least one embodiment is applied to a communication system 100. The communication system includes a network device 110, a terminal device 120, and a terminal device 130. In response to the network device 110 being a transmitter, the terminal device 120 or the terminal device 130 is a receiver. In response to the terminal device 120 or the terminal device 130 being a transmitter, the network device 110 is a receiver. The transmitter is also referred to as a sending apparatus, and the receiver is also referred to as a receiving apparatus. The network device is a base station, is a device obtained by integrating a base station and a base station controller, or is another device having a similar communication function.

The network device is an apparatus deployed in a radio access network to provide a wireless communication function for the terminal device. An access network device is a device having a wireless transceiver function or a chip that is disposed in the device. The device includes but is not limited to: an evolved NodeB (eNB), a radio network controller (RNC), a NodeB (NB), a base station controller (BSC), a base transceiver station (BTS), a home base station (for example, a home evolved NodeB, or a home NodeB, HNB), a baseband unit (BBU); an access point (AP), a radio relay node, a wireless backhaul node, a transmission point (TRP, or transmission point, TP), or the like in a wireless fidelity (Wi-Fi) system; a gNB or a transmission point (TRP or TP) in a 5G (for example, NR) system, or one antenna panel or a group of (including a plurality of antenna panels) antenna panels of a base station in the 5G system; or a network node that forms a gNB or a transmission point, for example, a baseband unit (BBU), a distributed unit (DU), a satellite, or an unmanned aerial vehicle.

In some deployment, the gNB includes a central unit (CU) and a DU. The gNB further includes a radio unit (RU). The CU implements some functions of the gNB, and the DU implements some functions of the gNB. For example, the CU implements functions of a radio resource control (RRC) layer and a packet data convergence protocol (PDCP) layer. The DU implements functions of a radio link control (RLC) layer, a media access control (MAC) layer, and a physical (PHY) layer. Information at the RRC layer eventually becomes information at the PHY layer (in other words, information sent through the PHY layer), or is converted from information at the PHY layer. Therefore, in this architecture, higher layer signaling, for example, RRC layer signaling or PDCP layer signaling, is also considered as being sent by the DU or sent by the DU and the RU. The access network device is a CU node, a DU node, or a device including the CU node and the DU node. In addition, the CU is classified as a network device in a radio access network (RAN), or the CU is classified as a network device in a core network CN. This is not limited herein.

The terminal device in at least one embodiment, which is also referred to as a terminal, is an entity configured to receive or transmit a signal on a user side, and is configured to send an uplink signal to a network device or receive a downlink signal from a network device. The terminal device includes a device that provides a user with voice and/or data connectivity, for example, includes a handheld device having a wireless connection function or a processing device connected to a wireless modem. The terminal device communicates with a core network over a RAN, and exchanges a voice and/or data with the RAN. The terminal device includes UE, a vehicle to everything (vehicle to x, V2X) terminal device, a wireless terminal device, a mobile terminal device, a device-to-device (D2D) terminal device, a machine to machine/machine type communications (M2M/MTC) terminal device, an internet of things (IOT) terminal device, a subscriber unit, a subscriber station, a mobile station, a remote station, an access point (AP), a remote terminal, an access terminal, a user terminal, a user agent, a user device, a wearable device, a vehicle-mounted device, an unmanned aerial vehicle, or the like.

As an example instead of a limitation, in at least one embodiment, the terminal device is alternatively a wearable device. The wearable device is also referred to as a wearable intelligent device, an intelligent wearable device, or the like, and is a general term of wearable devices that are intelligently designed and developed for daily wear by using a wearable technology, for example, glasses, gloves, watches, clothes, and shoes. The wearable device is a portable device that is directly worn on the body or integrated into clothes or an accessory of a user. The wearable device is not only a hardware device, but also implements a powerful function through software support, data exchange, and cloud interaction. In a broad sense, wearable intelligent devices include full-featured and large-sized devices that implement all or a part of functions without depending on smartphones, for example, smart watches or smart glasses, and include devices that dedicated to only one type of application function and collaboratively works with other devices such as smartphones, for example, various smart bands, smart helmets, or smart jewelry for monitoring physical signs.

In response to the various terminal devices described above being located in a vehicle (for example, placed in the vehicle or installed in the vehicle), the terminal devices are all considered as vehicle-mounted terminal devices. For example, the vehicle-mounted terminal devices are also referred to as on-board units (OBU).

In descriptions of at least one embodiment, the term “and/or” describes an association relationship between associated objects and indicates that three relationships exist. For example, A and/or B indicates the following three cases: Only A exists, both A and B exist, and only B exists. The character “/” generally indicates an “or” relationship between the associated objects. In at least one embodiment, “at least one” means one or more, and “a plurality of” means two or more. In addition, in description of at least one embodiment, terms such as “first” and “second” are merely used for distinguishing and description, but should not be understood as indicating or implying relative importance, or should not be understood as indicating or implying a sequence.

In the communication system in FIG. 1, to ensure security of communication between communication devices, coding processing is performed on information. Refer to an encoding and decoding procedure shown in FIG. 2. A source of a transmitter sequentially performs source encoding, channel encoding, and modulation, and then outputs a modulation symbol. After receiving the modulation symbol, a receiver sequentially performs demodulation, channel decoding, and source recovery to obtain a sink. The receiver obtains useful information based on the sink.

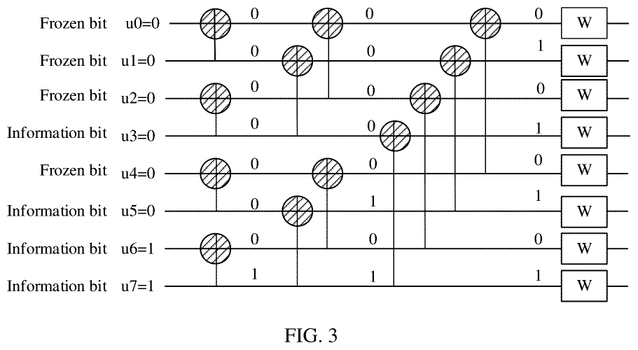

Polar is a channel coding scheme that is strictly proved to “reach” a Shannon channel capacity, has features such as good performance and low complexity, and currently has been determined by the 3rd generation partnership project (3GPP) as a 5G enhanced mobile broadband (eMBB) (uplink/downlink) control channel coding scheme. FIG. 3 shows a polar coding process. In response to performing polar, a transmitter determines an information bit and a frozen bit, where u₇, u₆, u₅, and u₃ are information bits (data), and u₄, u₂, u₁, and u₀ are frozen bits. An exclusive OR (XOR) operation is performed on the information bits and the frozen bits to obtain an encoded sequence, and the encoded sequence is transmitted to a receiver through a channel W. In actual application, the transmitter and the receiver agree that a value of frozen is 0. Values of bits u₀ and u₁ shown in FIG. 3 are still 0 after an XOR operation is performed, an encoded sequence 01010101 is obtained after an operation is performed on the information bits and the frozen bits, and the encoded sequence is mapped to modulation symbols, and then is transmitted on W.

To make transmitted modulation symbols conform to Gaussian distribution, a probabilistic shaping technology is introduced. Currently, in an online construction algorithm that is based on density evolution, a soft information distribution function obtained in a decoding process of each polarized subchannel on a left side of a fence diagram is calculated by using a given signal-to-noise ratio (SNR), and a channel capacity of each subchannel is obtained based on the soft information distribution function. For a sub-block of non-shaping bits, a location with higher reliability is selected as an information bit location; for a sub-block of shaping bits, a location with lower reliability is selected as a dynamic bit location. In this method, reliability of each sub-channel is to be calculated on line. Implementation complexity is high. In addition, there is a polar-based offline construction method, to be specific, based on a given sequence, information bits and frozen bits are sequentially read from the sequence. However, this solution cannot adapt to a usage of polar code construction in which probabilistic shaping is introduced.

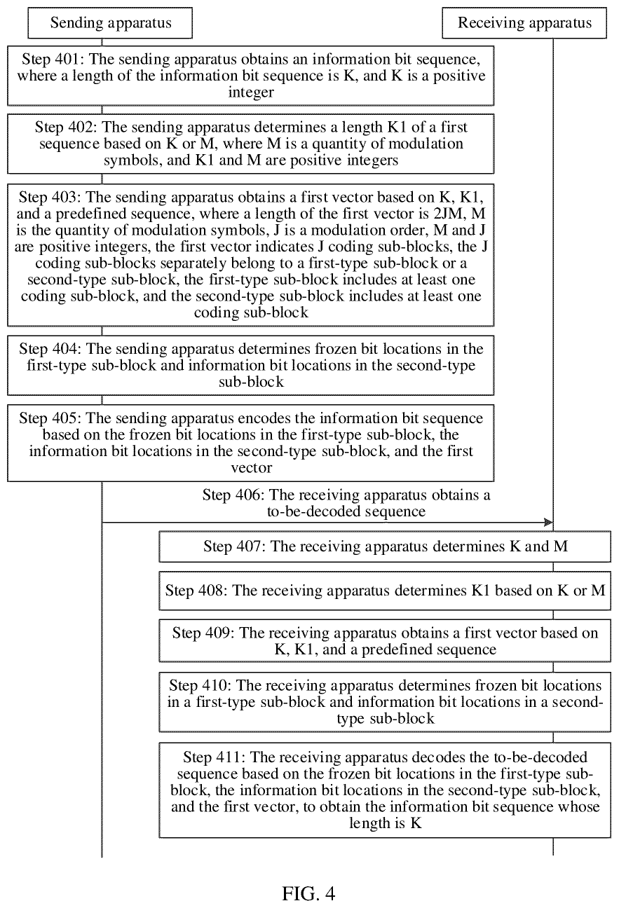

Based on this, at least one embodiment provides an encoding and decoding method, to perform encoding more efficiently in an offline case. FIG. 4 shows an encoding and decoding method provided in at least one embodiment. The encoding method is performed by a sending apparatus, and the decoding method is performed by a receiving apparatus. The sending apparatus is UE, a vehicle-mounted device, a terminal device, a module (for example, a chip) in the terminal device, or the like. The sending apparatus is alternatively a TRP, a gNB, a network device, a module (for example, a chip) in the network device, or the like. The receiving apparatus is the same as the foregoing sending apparatus. Details are not described herein. However, the sending apparatus and the receiving apparatus are different communication apparatuses. For example, the sending apparatus is a terminal device, and the receiving apparatus is a network device. This is not limited herein in at least one embodiment, and the following steps is performed:
Step 401: The sending apparatus obtains an information bit sequence, where a length of the information bit sequence is K, and K is a positive integer.
Step 402: The sending apparatus determines a length K1 of a first sequence based on K or M, where M is a quantity of modulation symbols, and K1 and M are positive integers.

The encoding and decoding method provided in at least one embodiment is applied to higher-order modulation, for example, 64 QAM, 256 QAM, or 1024 QAM. The information bit sequence is understood as a sequence that uses coding processing. The length (that is, a quantity) of the information bit sequence is determined, and the length of the information bit sequence is K. To improve robustness and reduce complexity during encoding, the information bit sequence is divided into the first sequence and a second sequence, and different coding processing is performed for different sequences. In actual application, in response to shaping being introduced during encoding, the first sequence is understood as a sequence for shaping. Certainly, in actual application, another encoding operation (an operation different from conventional polar coding) is introduced, and the first sequence is a sequence for another encoding operation. This is not limited in at least one embodiment. The following uses an example in which the first sequence is a sequence for shaping and the second sequence is a sequence on which shaping is not performed for description. However, in actual application, another encoding operation is not limited to shaping. A sum of the length of the first sequence and a length of the second sequence is the length of the information bit sequence. To be specific, in response to the length K of the information bit sequence being known and the length K1 of the first sequence being known, the length of the second sequence is K−K1.
Step 403: The sending apparatus obtains a first vector based on K, K1, and a predefined sequence, where a length of the first vector is 2JM, M is the quantity of modulation symbols, J is a modulation order, M and J are positive integers, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block.
Step 404: The sending apparatus determines frozen bit locations in the first-type sub-block and information bit locations in the second-type sub-block.
Step 405: The sending apparatus encodes the information bit sequence based on the frozen bit locations in the first-type sub-block, the information bit locations in the second-type sub-block, and the first vector.

After performing step 404, the sending apparatus obtains an encoded sequence, and transmits the encoded sequence to the receiving apparatus. However, in response to the encoded sequence being transmitted on a channel between the sending apparatus and the receiving apparatus, interference or the like exists. Therefore, after the encoded sequence is transmitted on the channel, the encoded sequence is a to-be-decoded sequence. The to-be-decoded sequence is understood as a scrambled encoded sequence.
Step 406: The receiving apparatus obtains the to-be-decoded sequence.
Step 407: The receiving apparatus determines K and M. Values of K and M are obtained by using indication signaling. The indication signaling is UCI, DCI, or the like, or is agreed upon with the sending apparatus in advance. This is not limited herein.
Step 408: The receiving apparatus determines K1 based on K or M.
Step 409: The receiving apparatus obtains a first vector based on K, K1, and a predefined sequence, where a length of the first vector is 2JM, M is a quantity of modulation symbols, J is a modulation order, M and J are positive integers, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block.
Step 410: The receiving apparatus determines frozen bit locations in the first-type sub-block and information bit locations in the second-type sub-block.
Step 411: The receiving apparatus decodes the to-be-decoded sequence based on the frozen bit locations in the first-type sub-block, the information bit locations in the second-type sub-block, and the first vector, to obtain the information bit sequence whose length is K.

In response to an encoding operation or a decoding operation being performed, a modulation scheme (for example, the modulation scheme is 64QAM higher-order modulation), the modulation order J being 3 (r=log₂(\sqrt{64})=3), and the quantity M of modulation symbols (the quantity of modulation symbols is preset, for example, agreed upon by the sending apparatus and the receiving apparatus) are determined, to construct the first vector whose length is 2JM based on K, K1, the predefined sequence, the modulation order, and the quantity of modulation symbols. A location of the information bit sequence corresponding to the first vector is determined based on the first vector (for example, in response to the information bit sequence being [0 1 0], and the first vector being [0 0 0 0 0 1 1 1], the information bit sequence corresponds to 111 in the first vector. In this case, in response to an encoding operation being performed, the 6^{th}, the 7^{th}, and the 8^{th} locations are set as information bit locations, and other locations are set as frozen bit locations). In addition, the information bit locations and the frozen bit locations are determined by using the first vector, and an encoding operation is efficiently performed based on the obtained frozen bit locations and the obtained information bit locations.

In addition, the first vector indicates the J coding sub-blocks, the J coding sub-blocks separately belong to the first-type sub-block or the second-type sub-block, the first-type sub-block includes at least one coding sub-block, and the second-type sub-block includes at least one coding sub-block. Because another encoding operation such as a shaping operation is introduced during encoding, the first-type sub-block is understood as a shaping sub-block. To ensure that a decoder, that is, the receiving apparatus, more quickly obtains the information bit sequence through decoding in response to another encoding operation being introduced, the information bit sequence is encoded based on the frozen bit locations in the first-type sub-block, the information bit locations in the second-type frozen bit, and the first vector, to improve decoding efficiency of the decoder.

In response to an encoding operation being performed in at least one embodiment, a solution (that is, online coding) of adjusting a coding policy based on a channel status is not used. Instead, the first vector is constructed based on the length of the information bit sequence, the length of the first sequence, and the predefined sequence, different coding sub-blocks are indicated based on the first vector, and the information bit sequence is encoded based on information bit locations and frozen bit locations in the different coding sub-blocks and the first vector. In this way, encoding and decoding efficiency is improved, and calculation complexity is reduced compared with online coding.

In an optional implementation, the sending apparatus or the receiving apparatus determines K1 in the following manner:
Manner 1: K1 is determined based on an index value corresponding to K or M.

For example, an index table of a correspondence between K and K1 is stored in the sending apparatus or the receiving apparatus, and K1 is directly read based on an index value in the index table. As shown in Table 1, an index number of an information bit sequence whose length is 111 is 001, and a length of a corresponding first sequence is 37. The sending apparatus or the receiving apparatus determines the length of the first sequence by obtaining the index number. In actual application, only one or more rows in the table are used. This is not limited in at least one embodiment. In addition, in Table 1, in actual storage, only the first column and the third column, or the second column and the third column is stored, and the length of the first sequence in the third column is directly determined based on a value of the first column or a value of the second column. This is not limited herein in at least one embodiment.

TABLE 1

| | Length (K) of an | Length (K1) of a |
|---|---|---|
| Index number (index) | information bit sequence | first sequence |
| 001 | 111 | 37 |
| 010 | 150 | 50 |
| 011 | 210 | 70 |
| . . . | . . . | . . . |

For example, an index table of a correspondence between M and K1 is stored in the sending apparatus or the receiving apparatus, and K1 is directly read based on an index value in the index table. As shown in Table 2, an index number of an information bit sequence whose M is 32 is 001, and a length of a corresponding first sequence is 23. The sending apparatus or the receiving apparatus determines the length of the first sequence by obtaining the index number. In actual application, only one or more rows in the table are used. This is not limited in at least one embodiment. In addition, in Table 2, in actual storage, only the first column and the third column, or the second column and the third column is stored, and the length of the first sequence in the third column is directly determined based on a value of the first column or a value of the second column. This is not limited herein in at least one embodiment.

TABLE 2

| | Quantity (M) of | Length (K1) of a |
|---|---|---|
| Index number (index) | modulation symbols | first sequence |
| 001 | 32 | 23 |
| 010 | 64 | 60 |
| 011 | 128 | 70 |
| . . . | . . . | . . . |

Manner 2:

The sending apparatus or the receiving apparatus determines K1 by using the following formula 1:

$$K 1 = ⌊ {log}_{2} {C}_{2 M}^{⌊ 2 {Mp}_{bias} ⌋} ⌋ \qquad Formula 1$$

K1 represents a length of the first sequence; M represents a quantity of modulation symbols; and p_{bias} represents a preset shaping probability.

The preset shaping probability is 0.3, 0.4, or the like, and is determined based on an actual usage. This is not limited in at least one embodiment. Alternatively, the preset shaping probability is directly obtained from signaling information, for example, UCI or DCI. This is not limited in at least one embodiment. For example, M is 5, and p_{bias} is 0.4. K1 is calculated according to the formula 1, where K1=└log₂C_{└2□5}^{2□5□0.4┘┘}=└log₂C₁₀⁴┘=└log₂210┘=7. Therefore, the length of the first sequence is 7.

Determining K1 in the manner 1 is simpler, and has a smaller calculation amount. In the manner 2, K1 is determined based on the quantity of modulation symbols and the preset shaping probability. Compared with the manner 1, in the manner 2, a calculation amount is increased, but reliability is higher and flexibility is higher. In addition, K1 calculation is not strictly limited to the foregoing calculation. A value is added to or subtracted from K1 after K1 is determined in the manner 1 or the manner 2. Impact on performance is also small.

In an optional implementation, the sending apparatus or the receiving apparatus determines a first index set Θ based on K, K1, and the predefined sequence, and obtain the first vector based on the first index set Θ, where a location index i in the first vector satisfies:
if i∈Θ, the location index i carries a first preset value; and
if i∉Θ, the location index i carries a second preset value, where the first preset value is different from the second preset value, 1≤i≤2JM, and i is a positive integer.

The predefined sequence is understood as a sequence that meets a mother code length (a sequence length meets 2^{N}, where N is a positive integer), for example, a sequence whose length is 8: [1, 2, 3, 5, 4, 6, 7, 8]; or is understood as another sequence, for example, a sequence pre-agreed upon by the sending apparatus and the receiving apparatus. This is not limited in at least one embodiment.

The first index set includes an element selected from the predefined sequence. For example, in response to the predefined sequence being [1 2 3 5 4 6 7 8], and sequence elements selected from the predefined sequence being 4, 6, 7, and 8, the first index set is {4, 6, 7, 8}. Alternatively, the first index set is an index set obtained by transforming the predefined sequence. For example, in response to the predefined sequence being [1 2 3 5 4 6 7 8], and based on K and K1, a change manner of the predefined sequence is subtracting 1 from all elements of the sequence to obtain the first index set, the first index set is {0, 1, 2, 4, 3, 5, 6, 7}. A manner of and a rule for determining the first index set are not limited herein in at least one embodiment.

In response to J being 2, and M being 2, the length of the first vector is 8 (2*2*2), the first index set Θ is {2, 3, 5, 6, 7}, and the location index in the first vector carries the first preset value or the second preset value. The first preset value is 1, and the second preset value is 0; or the first preset value is 0, and the second preset value is 1. This is not limited herein in at least one embodiment. Usually, the first preset value indicates a location of the information bit sequence. In response to the first preset value being 1, and the second preset value being 0, the first vector is 00110111. The information bit locations and the frozen bit locations are determined by using the first vector, so that an encoding operation is efficiently performed.

In an optional implementation, after the first index set is determined, the first vector is determined based on the first index set, where an element carried at a (2M(y−1)+1)^{th} location in the first vector to an element carried at a (2My)^{th} location in the first vector correspond to a y^{th} coding sub-block, 1≤y≤J, and y is a positive integer, that is, a length of each coding sub-block indicated by the first vector is 2M. For example, in response to the first vector being 10001111, J is 2, and M is 2, the length of the coding sub-block is 4, and the first vector indicates two coding sub-blocks, where the first coding sub-block corresponds to 1000, and the second coding sub-block corresponds to 1111.

After the first index set is determined based on K, K1, and the predefined sequence, the manner of obtaining the first vector based on the first index set improves coding efficiency and reduces coding processing complexity.

In an optional implementation, the sending apparatus or the receiving apparatus determines a first parameter T based on K and K1, and select T sequence elements from the predefined sequence to construct the first index set Θ. In this way, the first index set is quickly determined, so that the first vector is more quickly determined based on the first index set.

In an optional implementation, the sending apparatus or the receiving apparatus determines T by using the following formula 2:

### Manner 1:

$$T = 2 M + K - K 1 \qquad Formula 2$$

T represents the first parameter, M represents the quantity of modulation symbols, K represents the length of the information bit sequence, and K1 represents the length of the first sequence. For example, M is 5, K is 8, and K1 is 4. T is calculated according to the formula 2, where T=2*5+8−4=14.

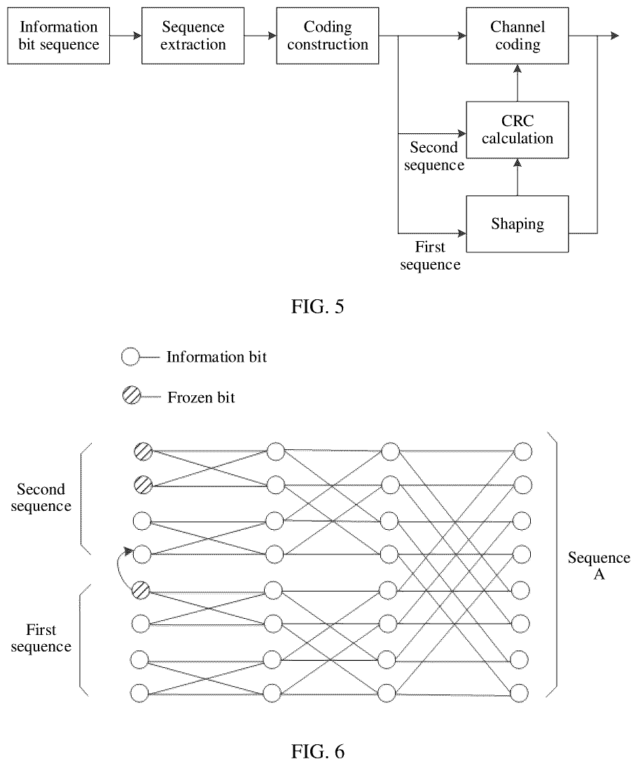

In response to the sending apparatus performing encoding, considering decoding performance of the receiving apparatus, in addition to encoding the information bit sequence based on the frozen bit locations in the first-type sub-block, the information bit locations in the second-type sub-block, and the first vector, the sending apparatus further performs shaping mapping and polar transform on the first sequence to obtain a third sequence; extract a fourth sequence from the third sequence based on the first vector, where an element in the fourth sequence is a value of an information bit location in the first-type sub-block, and a length of the fourth sequence is less than a length of the third sequence; perform CRC calculation on a fifth sequence to obtain a sixth sequence, where the fifth sequence includes a second sequence and the fourth sequence; and encode the sixth sequence and the second sequence. As shown in FIG. 5, after obtaining the information bit sequence, the sending apparatus performs an extraction operation on the information bit sequence to obtain the first sequence and the second sequence, and then performs coding construction based on the first sequence and the second sequence. After the first sequence is shaped and CRC calculation is performed on both the first sequence and the second sequence, the first sequence and the second sequence are output after channel coding is performed.

In response to performing, the CRC operation is performed in the following manner:
(1) Based on the length K1 of the first sequence and the length K−K1 of the second sequence, input information bits b₁, b₂, . . . , and b_{K} are grouped in the following manner:

$${u}_{i} = {b}_{i} ;$$

$${v}_{i} = {b}_{i + K - K 1} .$$

(2) vᵢ is shaped to obtain a bit sequence with a length of 2M, and the bit sequence is denoted as s₁, s₂, . . . , s_{2M}.
(3) Polar transform is performed on s₁, s₂, . . . , and s_{2M} to obtain the third sequence, and values corresponding to information bit locations are extracted from the third sequence based on 2M locations in the first-type sub-block that are indicated by the first vector, and are denoted as the fourth sequence. The fourth sequence is h₁, h₂, . . . , h_{SI}.
(4) The fourth sequence and the second sequence are used as input sequences of a CRC encoder to perform a CRC operation. For specific CRC calculation, refer to (T. V. Ramabadran and S. S. Gaitonde, “A tutorial on CRC computations,” in IEEE Micro, vol. 8, no. 4, pp. 62-75, August 1988, doi: 10.1109/40.7773). Details are not described herein.

In addition, in at least one embodiment, an input bit sequence of the CRC encoder is further determined in the following manner:

The second sequence and the fourth sequence are combined into a long sequence, that is, the fifth sequence, used as a sequence input to the CRC encoder. Alternatively, CRC calculation is performed only on a subset of the second sequence or the fourth sequence. This is not limited in at least one embodiment.

Correspondingly, during decoding, the receiving apparatus determines, through CRC check, whether a decoding error occurs.

Decoding performance is improved by introducing CRC.

Considering that there is CRC during encoding, the first parameter T is further related to a CRC length, and T is determined by using the following formula 3:

$$T = 2 M + K + L - K 1 \qquad Formula 3$$

T represents the first parameter, M represents the quantity of modulation symbols, K represents the length of the information bit sequence, K1 represents the length of the first sequence, and L represents the CRC length.

In addition, the first sequence is a plurality of bits, and there is also a plurality of first-type sub-blocks. Assuming that the first sequence is q sub-sequences, in response to the first parameter being related to the CRC length, the first parameter is determined by referring to the following formula 4:

$$T = 2 q M + K + L - {\sum }_{x = 1}^{q} {K}_{x , 1} \qquad Formula 4$$

T represents the first parameter, M represents the quantity of modulation symbols, K represents the length of the information bit sequence, q represents a quantity of sub-sequences of the first sequence, K1 represents the length of the first sequence, L represents the CRC length, and K_{x,1} represents a length of an x^{th} sub-sequence.

In response to the first sequence including a plurality of sub-sequences, K1 is determined by performing summation calculation on lengths of the plurality of sub-sequences. However, in actual application, alternatively, K1 is determined by performing joint calculation on the sub-sequences. For example, a plurality of sub-sequences of the first sequence are combined as one high-dimensional symbol, the first sequence is 3 bits, quantities of high-dimensional symbols are respectively n0, n1, and n2. In this case, K1=log₂(Cₙ₀₊ₙ₁₊ₙ₂ⁿ⁰*Cₙ₁₊ₙ₂ⁿ¹). In actual application, the value of K1 is alternatively determined in another manner in response to the first sequence being a plurality of sub-sequences. This is not limited in at least one embodiment.

Regardless of whether T is related to the CRC length or whether the first sequence is a plurality of bits, the sending apparatus or the receiving apparatus selects T sequence elements from the predefined sequence as the first index set according to a first rule, where the first rule includes one of the following: selecting T sequence elements forward from the last sequence element of the predefined sequence as the first index set, and selecting T sequence elements backward from the 1^{st} sequence element of the predefined sequence as the first index set. For example, the predefined sequence is [1 2 3 5 4 6 7 8], and T is 5. Five sequence elements are selected from the last sequence element forward as the first index set. For example, the first index set is {8, 7, 6, 4, 5}. Alternatively, T sequence elements are selected from the 1^{st} sequence element backward as the first index set. For example, the first index set is {1, 2, 3, 5, 4}. Alternatively, T sequence elements are selected from an element previous to the last sequence element of the predefined sequence as the first index set. For example, the first index set is {7, 6, 4, 5, 3}. In addition, in actual application, there is another selection manner. This is not limited in at least one embodiment.

In an optional implementation, after determining the first vector based on the first index set, the sending apparatus or the receiving apparatus determines the frozen bit locations in the first-type sub-block and the information bit locations in the second-type sub-block; select F information bit locations from the information bit locations in the second-type sub-block, where F is a length of frozen bits in the first-type sub-block, and F is an integer; and assign values of F frozen bit locations in the first-type sub-block to the F information bit locations in the second-type sub-block.

Assigning the values of the F frozen bit locations in the first-type sub-block to the F information bit locations in the second-type sub-block is understood as directly duplicating the values of the F frozen bit locations in the first-type sub-block to the information bit locations in the second-type sub-block, or is understood as assigning the values of the F frozen bit locations in the first-type sub-block to the information bit locations in the second-type sub-block through encoding (scrambling, exclusive OR, or the like). In actual application, a value assignment manner is not limited in at least one embodiment.

In addition, in actual application, the length of the frozen bits in the first-type sub-block is alternatively F1 (if a length of all frozen bits in the first-type sub-block is 5, F1 is 3 or another value less than 5), and F2 information bit locations is selected from the information bit locations in the second-type sub-block. A value of F2 is different from that of F1. This is not limited herein in at least one embodiment, provided that a relationship between the frozen bits of the first-type sub-block and information bits of the second-type sub-block is determined.

In actual application, there is a plurality of second-type sub-blocks, there is a plurality of first-type sub-block, and lengths of the first-type sub-block and the second-type sub-block are the same. After the frozen bit locations are determined in the first-type sub-block, a quantity of information bits that exists in the second-type sub-block is far greater than a quantity of frozen bits in the first-type sub-block. In response to the information bits in the second-type sub-block being selected, the information bits with the largest indexes in the second-type sub-block is selected, or information bits with the smallest row weight (that is, the first preset value is the smallest) in the second-type sub-block is selected. Certainly, random selection is performed. After some information bits of one of the second-type sub-blocks are selected, some information bits of another second-type sub-block are selected, to construct, with the frozen bits in the first-type sub-block, a check relationship between the frozen bits in the first-type sub-block and the information bits in the second-type sub-block according to a preset check rule. As shown in FIG. 6, the length of the information bit sequence is assumed to be 8, where the length of the first sequence is 4, and the length of the second sequence is 4. Frozen bits are represented by using shadow-filled circles, and circles that are not filled are information bits. There is one frozen bit in the first sequence, and there are two information bits in the second sequence. In the figure, a check relationship is constructed only by using the frozen bit of the first sequence and the 2^{nd} information bit (counted from top to bottom) of the second sequence. However, in actual application, the check relationship is alternatively established between the frozen bit of the first sequence and the 1^{st} information bit of the second sequence. Coding processing is performed based on the check relationship between the frozen bits of the first sequence and the information bits of the second sequence, and locations and values of information bits and the frozen bits of the sequences, to obtain an encoded sequence, that is, a sequence A on the right side of FIG. 6. In at least one embodiment, the check relationship between the frozen bits of the first-type sub-block and the information bits of the second-type sub-block is determined, to help the receiving apparatus perform decoding more quickly.

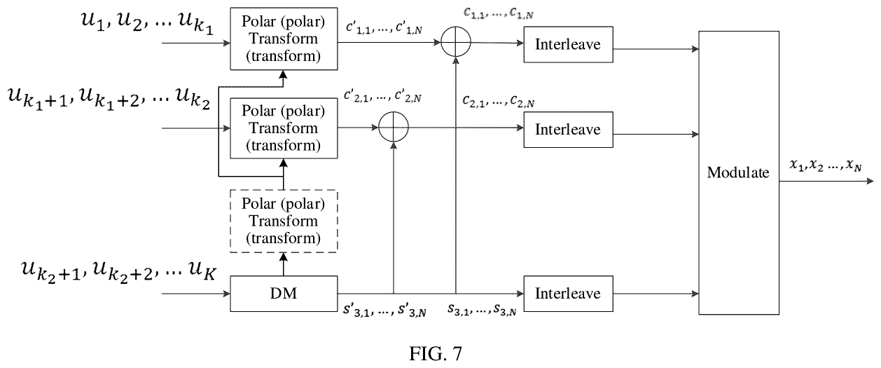

The foregoing mentions shaping, but does not mention how to perform a shaping operation. An encoding operation based on polar shaping is understood by referring to FIG. 7. FIG. 7 is merely an example for description. In actual application, polar shaping that is applied to at least one embodiment is not limited.

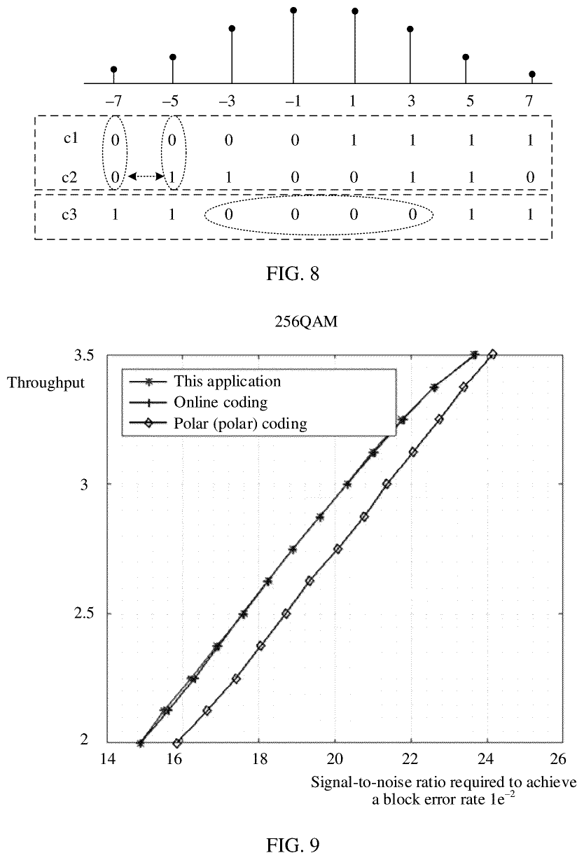

The sending apparatus divides the information bit sequence whose length is K into three groups, which are denoted as U₁=u₁, u₂, . . . uₖ_{₁}, U₂=uₖ_{₁}₊₁, uₖ_{₁}₊₂, . . . uₖ_{₂}, and U₃=uₖ_{₂}₊₁, uₖ_{₂}₊₂, . . . U_{K}. The sequence U₃ is mapped by using a distribution matcher, to obtain S′₃=s′_{3,1}, . . . , s′_{3,N}. N is a symbol sequence length. m_{3,1}, . . . , m_{3,N} is obtained by performing polar transform on S′₃. Polar channel coding is performed on a sequence M_{3,F}={m_{3,i}, i∈F} and U₁, U₂ separately, to obtain C′₁=c′_{1,1}, . . . , c′_{1,N}, and C′₂=c′_{2,1}, . . . , c′_{2,N}. C′₁, C′₂, and S′₃ are concatenated as a long code, to obtain C₁, C₂, and S₃. Polar transform is performed on c′_{1,i}, c′_{2,i}, and s′_{3,i}, to obtain c_{1,i}, c_{2,i}, and s_{3,i}. Intra-block interleaving is separately performed on C₁, C₂ and S₃, to obtain C₁, C₂ and S₃. C₁, C₂, and S₃ are mapped to an 8-amplitude shift keying (ASK) modulation symbol, which is denoted as X, where c_{1,i}, c_{2,i}, and s_{3,i} are mapped to xᵢ. In response to a sequence being mapped to a modulation symbol, refer to the following rules:
(1) The Gray mapping rule is met, that is, adjacent symbols have only one different bit.
(2) Mapping of the last sequence complies with that bits in a middle half differ from bits on both sides. For example, s₃ is [1 1 0 0 0 0 1 1]. Four bits in the middle are different from four bits on both sides, as shown in FIG. 8.

In addition, FIG. 9 is a schematic diagram of simulation results of online coding and coding without shaping processing during coding according to at least one embodiment. A horizontal coordinate is a signal-to-noise ratio used to reach a block error rate 1e⁻², and a vertical coordinate is a throughput. FIG. 9 shows a case in which higher-order modulation is 256QAM. A line of “*” represents a solution of at least one embodiment (shaping shown in FIG. 7 is used), a line of “|” represents an online coding method, and a line of “␣” represents a polar coding solution (without shaping). Offline coding construction in at least one embodiment achieves a performance gain almost consistent with online coding construction, and is obviously better than the solution without shaping.

In actual application, lengths of many to-be-encoded sequences do not meet a mother code length, and the to-be-encoded sequences are to be preprocessed through rate matching. Usually, the rate matching includes puncturing, shortening, or pre-freezing. A specific rate matching manner is not limited in actual application. The following uses pre-freezing as an example. The to-be-encoded sequence is preprocessed. In a pre-freezing or puncturing manner, that the to-be-encoded sequence meets a mother code length usage. In at least one embodiment, the to-be-encoded sequence is a sequence C obtained by processing the information bit sequence whose length is K, and a length of the sequence C is 2MJ, which is the same as the length of the first vector. In actual application, the following situations are considered:
Case 1: The modulation order does not meet the mother code length.

In response to J≠2^{N}, |2^{┌log}^{₂}^{(J)┐}−J| encoding sub-blocks of the sequence C whose length is 2M is pre-frozen, and information bits and frozen bits that correspond to the |2^{┌log}^{₂}^{(J)┐}−J| pre-frozen encoding sub-blocks of the sequence C whose length is 2M are removed, where N is a positive integer. For example, in response to the modulation order being 3, which does not meet a mother code length usage, the last coding sub-block whose length is 2M is pre-frozen, to obtain a sequence that meets the mother code length usage.
Case 2: The modulation symbol does not meet the mother code length.

In response to M≠2^{X}, the sequence C is divided into J sub-sequences whose lengths are 2·2^{┌log}^{₂}^{(M)┐}, and 2□|2^{┌log}^{₂}^{(M)┐}−M information bits of each sub-sequence are pre-frozen, where X is a positive integer. For example, in response to the modulation symbol being 7, which does not meet a mother code length usage, one sub-sequence is pre-frozen.

Performing rate matching in the foregoing manner not only improves coding efficiency but also reads a short sequence from a long sequence. A lower-order modulation sequence is read from a higher-order modulation sequence during sequence construction, and any long sequence is extracted from a mother code length sequence. A sequence is constructed through encoding. In this way, storage space of a device is saved, and storage of a large quantity of sequences is avoided.

The following shows a sequence A and a sequence B, both of which are sequences with a length of 256 and a modulation scheme of 16 ASK. A modulation order corresponding to 16 ASK is 4, and a modulation symbol is 32. A sequence whose length is less than 256 is constructed based on the foregoing rate matching method. For example, a sequence with a length of 192 is constructed by pre-freezing a coding sub-block with a length of 64. Alternatively, another sequence whose length is less than 256 is constructed. Details are not described herein in at least one embodiment.

In the following descriptions, in response to encoded sub-sequences corresponding to different modulation bits undergoing different (or same) interleaving, the sequence A (or the sequence B) is used for construction.

Sequence A=[1 257 513 769 2 3 5 9 17 33 4 6 65 10 7 18 11 19 129 13 34 66 21 35 25 37 8 130 67 12 41 69 258 131 20 14 49 15 73 22 133 36 259 27 81 38 26 23 137 39 97 68 42 261 514 145 29 70 43 50 265 75 161 193 71 45 132 82 51 74 16 134 53 273 515 24 135 77 138 83 57 289 28 260 98 40 85 139 146 262 517 30 44 99 89 141 31 321 147 72 162 46 101 52 149 266 521 47 263 76 105 163 54 194 274 529 153 267 78 165 55 84 58 275 113 385 136 79 195 86 59 169 269 545 140 290 100 87 61 90 197 322 516 142 277 102 148 177 143 32 201 291 518 91 281 150 103 106 164 93 293 577 48 264 209 386 151 154 166 107 323 522 56 268 114 297 155 80 109 225 325 519 167 387 530 196 60 170 115 157 276 523 88 270 198 305 117 171 62 178 271 531 92 329 199 278 173 121 202 63 389 641 144 292 525 104 283 179 337 94 203 108 294 546 181 282 152 279 210 95 205 393 578 156 295 533 211 353 110 324 185 116 298 547 168 401 226 285 158 111 118 213 326 537 172 299 549 227 306 217 331 159 119 417 520 174 449 642 122 327 200 301 180 388 579 229 338 524 175 307 123 330 204 64 272 553 182 390 581 233 309 125 280 206 183 391 643 770 212 333 532 186 394 241 339 207 313 526 96 284 561 214 354 187 296 341 228 395 527 112 402 585 215 286 189 300 218 355 534 230 345 645 160 397 548 120 287 403 219 328 539 231 418 593 234 302 176 357 308 124 405 550 771 221 303 538 184 332 535 361 419 235 310 649 126 450 551 242 409 208 334 188 421 609 237 311 580 127 340 554 314 369 243 392 657 245 335 541 190 451 582 342 315 216 425 555 773 220 396 562 356 587 343 317 346 232 453 673 249 398 705 191 358 583 404 433 222 399 557 777 236 288 644 457 594 347 406 223 359 563 238 362 586 244 420 528 349 304 239 465 646 785 246 407 565 410 536 422 363 128 312 647 370 589 411 650 336 365 192 481 595 801 247 423 569 452 540 316 426 371 250 413 610 772 251 344 552 454 597 373 651 427 253 318 658 434 542 348 556 455 429 224 377 611 774 458 601 319 653 400 543 360 240 435 659 833 350 584 459 674 364 437 252 408 558 778 466 613 351 564 461 661 412 248 467 559 775 366 588 441 617 372 675 424 482 566 786 414 706 367 665 374 469 254 428 590 779 483 677 473 567 415 596 375 570 787 430 625 378 648 456 591 436 255 485 707 897 431 598 781 379 571 460 681 320 652 802 438 612 489 599 381 462 573 834 439 602 468 709 442 654 256 497 614 789 463 660 803 352 689 470 655 443 544 793 484 713 805 368 603 471 662 445 615 776 474 618 486 676 605 416 560 898 376 721 835 475 663 487 666 490 678 780 432 619 809 380 568 477 626 837 440 667 899 491 592 621 382 737 788 498 679 782 464 708 572 444 682 817 493 627 783 383 669 600 499 710 841 501 629 790 683 901 574 446 690 804 472 604 795 476 711 488 685 849 505 633 806 714 575 447 656 794 478 616 791 691 905 606 492 715 807 479 620 865 693 836 494 664 810 500 722 913 607 717 495 668 797 723 838 622 811 502 697 818 384 628 843 680 929 738 448 670 961 623 839 630 813 503 725 900 684 850 739 819 506 729 842 507 671 784 631 902 509 686 821 634 792 712 903 692 480 741 845 687 906 635 851 496 508 504 510 511 512 716 576 694 745 637 718 695 724 698 753 719 608 726 699 740 624 727 701 730 742 672 632 731 743 746 688 636 733 696 747 638 754 720 700 749 639 755 757 702 728 732 744 761 703 734 748 735 750 756 751 758 640 704 759 762 763 765 736 752 764 760 766 767 768 825 796 866 808 853 907 914 798 812 867 857 909 799 915 840 930 814 869 820 917 815 844 873 931 822 962 921 846 933 823 852 826 881 904 847 963 854 827 937 908 868 855 829 858 965 910 870 916 945 911 800 969 859 918 871 874 932 861 816 977 919 922 934 875 824 882 923 848 877 993 935 964 828 938 883 925 856 966 885 939 830 946 860 967 941 889 970 831 912 872 947 862 971 876 949 920 978 863 973 924 979 878 953 884 936 994 926 879 886 981 940 995 985 927 887 942 890 968 948 997 943 891 972 832 950 1001 893 974 951 980 954 1009 975 864 982 955 996 880 983 957 986 998 928 888 987 999 1002 944 892 989 952 1003 894 1010 976 956 1005 895 1011 1013 958 984 988 1000 1017 959 990 1004 991 1006 1012 1007 1014 896 960 1015 1018 1019 1021 992 1008 1020 1016 1022 1023 1024]

Sequence B=[1 257 513 2 3 5 9 17 33 4 6 65 10 7 18 11 19 129 13 34 66 21 35 25 37 8 130 67 12 41 69 131 258 20 14 49 15 73 22 133 36 27 81 38 26 23 137 39 97 68 42 145 29 70 43 50 75 161 193 71 45 132 82 51 74 16 134 53 24 135 77 138 83 57 28 98 40 85 139 146 30 44 99 89 141 31 147 72 162 46 101 52 149 47 76 105 163 54 194 153 78 165 55 84 769 58 113 136 79 195 86 59 169 140 259 100 87 61 90 197 142 102 148 177 143 32 201 91 150 103 106 261 514 164 93 48 209 151 154 166 107 265 56 114 155 80 109 225 167 196 273 60 170 115 157 88 198 117 171 289 515 62 260 178 92 199 173 121 202 63 262 144 104 179 94 203 108 181 152 321 517 210 266 95 205 156 211 110 185 263 116 274 168 226 158 111 118 213 172 267 521 227 275 217 385 159 119 174 122 269 529 200 290 180 322 229 175 123 204 64 277 545 182 291 233 281 125 206 183 212 293 516 186 264 241 386 207 96 214 187 323 518 228 268 112 297 215 325 189 218 387 577 230 276 160 270 120 305 219 231 271 522 234 329 176 278 124 389 221 292 184 283 519 235 337 530 126 294 242 282 208 279 523 188 393 237 295 353 324 127 298 531 243 401 641 245 285 190 326 299 216 306 525 220 331 546 232 417 449 327 301 249 388 578 191 338 533 222 307 330 272 236 390 547 223 309 537 280 391 333 394 238 339 549 244 313 520 284 642 354 296 341 239 395 579 246 402 524 286 300 355 345 397 128 287 553 192 403 581 328 643 418 302 357 247 308 532 405 526 303 561 332 361 419 310 250 450 527 251 409 585 334 534 421 311 340 253 314 645 369 548 392 539 335 451 342 315 425 593 396 550 356 538 343 535 317 346 453 224 398 649 358 551 404 609 433 580 399 288 240 457 554 347 657 406 541 359 362 420 349 582 304 555 465 562 407 587 410 673 422 252 363 705 312 583 370 557 411 336 365 481 644 423 594 452 563 316 586 426 528 371 413 248 344 646 454 565 373 536 427 647 318 434 589 348 650 455 595 429 569 377 458 319 400 540 360 610 435 552 350 597 459 364 651 437 658 408 542 466 556 351 611 461 601 254 412 653 770 467 543 366 659 441 584 372 674 424 558 482 613 414 564 367 374 469 661 428 559 483 588 473 617 415 675 566 375 706 430 665 378 590 456 677 567 436 596 771 485 570 431 625 379 648 460 591 320 707 438 598 489 571 381 681 652 462 612 773 439 599 468 573 442 602 709 255 497 654 777 463 614 352 660 470 689 655 544 443 713 785 484 603 368 662 615 618 471 676 801 445 605 474 560 721 663 486 666 416 678 376 619 475 568 626 487 667 772 490 592 432 621 737 679 380 708 774 477 572 833 682 627 669 440 600 778 491 710 382 629 683 574 498 690 775 464 604 786 711 685 633 444 714 779 493 575 383 656 616 691 499 606 787 501 715 897 620 693 664 446 722 781 472 607 802 717 668 723 476 622 834 488 697 789 628 680 738 505 670 803 623 793 630 725 447 684 805 478 739 776 729 671 631 492 686 898 634 835 712 692 256 479 741 780 494 687 809 635 837 716 500 576 899 694 788 745 637 495 718 782 695 817 724 783 698 502 753 841 719 790 608 726 384 699 901 740 804 624 795 727 448 701 849 730 806 742 794 503 672 791 632 905 731 807 743 506 746 865 507 688 509 480 496 508 504 510 511 512 636 733 696 747 638 754 720 700 749 639 755 757 702 728 732 744 761 703 734 748 735 750 756 751 758 640 704 759 762 763 765 736 752 764 760 766 767 768 836 810 913 797 838 811 818 843 929 961 839 813 900 850 819 842 784 902 821 792 903 845 906 851 825 796 866 808 853 907 914 798 812 867 857 909 799 915 840 930 814 869 820 917 815 844 873 931 822 962 921 846 933 823 852 826 881 904 847 963 854 827 937 908 868 855 829 858 965 910 870 916 945 911 800 969 859 918 871 874 932 861 816 977 919 922 934 875 824 882 923 848 877 993 935 964 828 938 883 925 856 966 885 939 830 946 860 967 941 889 970 831 912 872 947 862 971 876 949 920 978 863 973 924 979 878 953 884 936 994 926 879 886 981 940 995 985 927 887 942 890 968 948 997 943 891 972 832 950 1001 893 974 951 980 954 1009 975 864 982 955 996 880 983 957 986 998 928 888 987 999 1002 944 892 989 952 1003 894 1010 976 956 1005 895 1011 1013 958 984 988 1000 1017 959 990 1004 991 1006 1012 1007 1014 896 960 1015 1018 1019 1021 992 1008 1020 1016 1022 1023 1024]

FIG. 10 shows a case in which a higher-order modulation is 256QAM. A horizontal coordinate is a symbol quantity, and a vertical coordinate is a signal-to-noise ratio used to reach a block error rate 1e⁻². A dashed line is a simulation effect diagram of the solution in at least one embodiment, and a solid line is a simulation effect diagram of online coding. Performance of rate matching in at least one embodiment is basically the same as that of online construction.

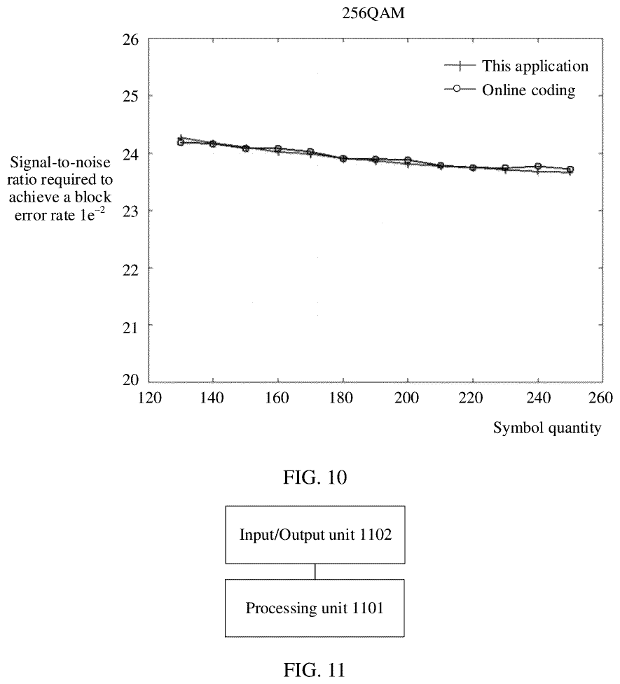

Based on a same concept, at least one embodiment provides a communication apparatus, as shown in FIG. 11, including a processing unit 1101 and an input/output unit 1102. In actual application, the input/output unit is implemented by using a same data processing chip, or is implemented by using different data processing chips. This is not limited in at least one embodiment. The communication apparatus is the foregoing sending apparatus and the foregoing receiving apparatus. The input/output unit is referred to as a transceiver unit, a communication unit, or the like. In response to the communication apparatus being a network device, the input/output unit is a transceiver, and the processing unit is a processor. In response to the communication apparatus being a module (for example, a chip) in a network device, the input/output unit is an input/output interface, an input/output circuit, an input/output pin, or the like, and is also referred to as an interface, a communication interface, an interface circuit, or the like. The processing unit is a processor, a processing circuit, a logic circuit, or the like.

In response to the communication apparatus being a sending apparatus, the input/output unit 1102 is configured to obtain an information bit sequence, where a length of the information bit sequence is K, and K is a positive integer. The processing unit 1101 is configured to: determine a length K1 of a first sequence based on K or M, where M is a quantity of modulation symbols, and K1 and M are positive integers; obtain a first vector based on K, K1, and a predefined sequence, where a length of the first vector is 2JM, M is the quantity of modulation symbols, J is a modulation order, M and J are positive integers, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block; determine frozen bit locations in the first-type sub-block and information bit locations in the second-type sub-block; and encode the information bit sequence based on the frozen bit locations in the first-type sub-block, the information bit locations in the second-type sub-block, and the first vector.

In response to the communication apparatus being a receiving apparatus, the input/output unit 1102 is configured to: obtain a to-be-decoded sequence; and determine K and M, where K is a length of an information bit sequence, and M is a quantity of modulation symbols. The processing unit 1101 is configured to: determine K1 based on K or M, where K, K1, and M are positive integers; obtain a first vector based on K, K1, and a predefined sequence, where a length of the first vector is 2JM, J is a modulation order, J is a positive integer, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block; determine frozen bit locations in the first-type sub-block and information bit locations in the second-type sub-block; and decode the to-be-decoded sequence based on the frozen bit locations in the first-type sub-block, the information bit locations in the second-type sub-block, and the first vector, to obtain the information bit sequence whose length is K.

The encoding method provided in at least one embodiment is applied to higher-order modulation, for example, 64 QAM, or 256QAM. The information bit sequence is understood as a sequence that uses coding processing, or is understood as a to-be-encoded sequence. An information bit sequence length (that is, an information bit quantity) is determined, and the length of the information bit sequence is K. To improve robustness and reduce complexity during encoding, the information bit sequence is divided into the first sequence and a second sequence, and different coding processing is performed for different sequences. In actual application, in response to shaping being introduced during encoding, the first sequence is understood as a sequence for shaping. Certainly, in actual application, another encoding operation (an operation different from conventional polar coding) is introduced, and the first sequence is a sequence for another encoding operation. This is not limited in at least one embodiment.

In addition, the predefined sequence is understood as a sequence that meets a mother code length (a sequence length meets 2^{N}, where N is a positive integer), for example, a sequence whose length is 8: [1, 2, 3, 5, 4, 6, 7, 8]; or is understood as another sequence, for example, a sequence pre-agreed upon by the sending apparatus and the receiving apparatus. This is not limited in at least one embodiment.

In response to an encoding operation being performed, a modulation scheme (for example, the modulation scheme is 64QAM higher-order modulation), the modulation order J being 3 (r=log₂(\sqrt{64})=3), and the quantity M of modulation symbols (the quantity of modulation symbols is preset, for example, agreed upon by the sending apparatus and the receiving apparatus) is to be determined, to construct the first vector whose length is 2JM based on K, K1, the predefined sequence, the modulation order, and the quantity of modulation symbols. A location of the information bit sequence corresponding to the first vector is determined based on the first vector (for example, in response to the information bit sequence being [0 1 0], and the first vector being [0 0 0 0 0 1 1 1], the information bit sequence corresponds to 111 in the first vector. In this case, in response to an encoding operation being performed, the 6^{th}, the 7^{th}, and the 8^{th} locations are set as information bit locations, and other locations are set as frozen bit locations). In addition, the information bit locations and the frozen bit locations are determined by using the first vector, and an encoding operation is efficiently performed based on the obtained frozen bit locations and the obtained information bit locations.

In addition, the first vector indicates the J coding sub-blocks, the J coding sub-blocks separately belong to the first-type sub-block or the second-type sub-block, the first-type sub-block includes at least one coding sub-block, and the second-type sub-block includes at least one coding sub-block. Because another encoding operation such as a shaping operation is introduced during encoding, the first-type sub-block is understood as a shaping sub-block. To ensure that a decoder, that is, the receiving apparatus, more quickly obtains the information bit sequence through decoding in response to another encoding operation being introduced, the information bit sequence is encoded based on the frozen bit locations in the first-type sub-block, the information bit locations in the second-type frozen bit, and the first vector, to improve decoding efficiency of the decoder.

In response to an encoding operation being performed in at least one embodiment, a solution (that is, online coding) of adjusting a coding policy based on a channel status is not used. Instead, the first vector is constructed based on the length of the information bit sequence, the length of the first sequence, and the predefined sequence, different coding sub-blocks are indicated based on the first vector, and the information bit sequence is encoded based on information bit locations and frozen bit locations in the different coding sub-blocks and the first vector. In this way, encoding efficiency is improved, and calculation complexity is reduced compared with online coding.

In an optional implementation, the processing unit 1101 is configured to: determine a first index set Θ based on K, K1, and the predefined sequence, and obtain the first vector based on the first index set Θ, where a location index i in the first vector satisfies: in response to i∈Θ, the location index i carries a first preset value; and in response to i∉Θ, the location index i carries a second preset value, where the first preset value is different from the second preset value, 1≤i≤2JM, and i is a positive integer. After the first index set is determined based on K, K1, and the predefined sequence, the first vector is obtained based on the first index set. In this way, information bit locations and check bit locations are directly obtained, thereby reducing coding construction complexity.

In an optional implementation, the first preset value is 1, and the second preset value is 0; or the first preset value is 0, and the second preset value is 1. This is not limited herein in at least one embodiment. Usually, the first preset value indicates a location of the information bit sequence.

In an optional implementation, an element carried at a (2M(y−1)+1)^{th} location in the first vector to an element carried at a (2My)^{th} location in the first vector correspond to a y^{th} coding sub-block, 1≤y≤J, and y is a positive integer. In other words, lengths of the coding sub-blocks indicated by the first vector are all 2M.

In an optional implementation, the processing unit 1101 is further configured to: select F information bit locations from the information bit locations in the second-type sub-block, where F is a length of frozen bits in the first-type sub-block, and F is an integer; and assign values of the F frozen bit locations in the first-type sub-block to the F information bit locations in the second-type sub-block.

Assigning the values of the F frozen bit locations in the first-type sub-block to the F information bit locations in the second-type sub-block is understood as directly duplicating the values of the F frozen bit locations in the first-type sub-block to the information bit locations in the second-type sub-block, or is understood as assigning the values of the F frozen bit locations in the first-type sub-block to the information bit locations in the second-type sub-block through encoding (scrambling, exclusive OR, or the like). In actual application, a value assignment manner is not limited in at least one embodiment.

In addition, in actual application, the length of the frozen bits in the first-type sub-block is alternatively F1 (if a length of all frozen bits in the first-type sub-block is 5, F1 is 3 or another value less than 5), and F2 information bit locations is selected from the information bit locations in the second-type sub-block. A value of F2 is different from that of F1. This is not limited herein in at least one embodiment, provided that a relationship between the frozen bits of the first-type sub-block and information bits of the second-type sub-block is determined. The relationship between the frozen bits of the first-type sub-block and the information bits of the second-type sub-block is determined, to help the receiving apparatus perform decoding more quickly.

In an optional implementation, the processing unit 1101 of the sending apparatus is further configured to: perform shaping mapping and polar transform on the first sequence to obtain a third sequence; extract a fourth sequence from the third sequence based on the first vector, where an element in the fourth sequence is a value of an information bit location in the first-type sub-block, and a length of the fourth sequence is less than a length of the third sequence; perform cyclic redundancy check CRC calculation on a fifth sequence to obtain a sixth sequence, where the fifth sequence includes a second sequence and the fourth sequence; and encode the sixth sequence and the second sequence. Decoding performance is improved by introducing CRC.

In an optional implementation, K1 is determined in the following manner:
manner 1: determining K1 based on an index value corresponding to K or M; or
manner 2:
determining K1 by using the following formula:

$$K 1 = {log}_{2} {C}_{2 M}^{⌊ 2 {Mp}_{bias} ⌋} ,$$

where
K1 represents a length of the first sequence; M represents a quantity of modulation symbols; and p_{bias} represents a preset shaping probability.

Determining K1 in the manner 1 is simpler, and has a smaller calculation amount. In the manner 2, K1 is determined based on the quantity of modulation symbols and the preset shaping probability. Compared with the manner 1, in the manner 2, a calculation amount is increased, but reliability is higher and flexibility is higher.

In an optional implementation, the processing unit 1101 is configured to: determine a first parameter T based on K and K1, and select T sequence elements from the predefined sequence to construct the first index set Θ. In this way, the first index set is quickly determined, so that the first vector is more quickly determined based on the first index set.

In an optional implementation, T is determined in the following manner:
manner 1:

$$T = 2 M + K - K 1 ,$$

where
T represents the first parameter, M represents the quantity of modulation symbols, K represents the length of the information bit sequence, and K1 represents the length of the first sequence: or
manner 2:
the first parameter is further related to a CRC length, and T is determined by using the following formula:

$$T = 2 M + K + L - K 1 ,$$

where

T represents the first parameter, M represents the quantity of modulation symbols, K represents the length of the information bit sequence, K1 represents the length of the first sequence, and L represents the CRC length.

The first parameter determined in the foregoing two manners is more reliable, so that coding efficiency is improved during coding, and coding complexity is reduced. In addition, the first sequence is a plurality of bits, and there is also a plurality of first-type sub-block. Assuming that the first sequence is q sub-sequences, in response to the first parameter being related to the CRC length, the first parameter is determined by referring to the following formula:

$$T = 2 q M + K + L - {\sum }_{x = 1}^{q} {K}_{x , 1} ,$$

where

T represents the first parameter, M represents the quantity of modulation symbols, K represents the length of the information bit sequence, q represents a quantity of sub-sequences of the first sequence, K1 represents the length of the first sequence, L represents the CRC length, and K_{x,1} represents a length of an x^{th} sub-sequence.

In an optional implementation, the processing unit 1101 is configured to:
select T sequence elements from the predefined sequence as the first index set according to a first rule, where the first rule includes one of the following: selecting T sequence elements forward from the last sequence element of the predefined sequence as the first index set, and selecting T sequence elements backward from the 1^{st} sequence element of the predefined sequence as the first index set.

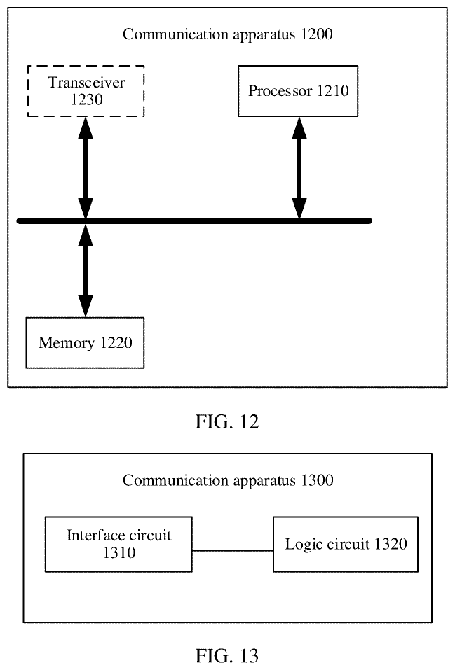

In addition, FIG. 12 shows a communication apparatus 1200 further provided in at least one embodiment. For example, the communication apparatus 1200 is a chip or a chip system. Optionally, in this embodiment of at least one embodiment, the chip system includes a chip, or includes the chip and another discrete device.

The communication apparatus 1200 includes at least one processor 1210, and the communication apparatus 1200 further includes at least one memory 1220, configured to store a computer program, program instructions, and/or data. The memory 1220 is coupled to the processor 1210. The coupling in at least one embodiment is an indirect coupling or a communication connection between apparatuses, units, or modules in an electrical form, a mechanical form, or another form, and is used for information exchange between the apparatuses, the units, or the modules. The processor 1210 performs a cooperative operation with the memory 1220. The processor 1210 executes the computer program stored in the memory 1220. Optionally, the at least one memory 1220 is also integrated with the processor 1210.

Optionally, in actual application, the communication apparatus 1200 includes or does not include a transceiver 1230. A dashed box is used as an example in the figure. The communication apparatus 1200 exchanges information with another device via the transceiver 1230. The transceiver 1230 is a circuit, a bus, a transceiver, or any other apparatus that is configured to exchange information.

In at least one embodiment, the communication apparatus 1200 is applied to the foregoing terminal device, or is the foregoing sending apparatus, or is the foregoing receiving apparatus. The memory 1220 stores a computer program, program instructions, and/or data used for implementing a function of the terminal device in any one of the foregoing embodiments. The processor 1210 executes the computer program stored in the memory 1220, to complete the method in any one of the foregoing embodiments.

A specific connection medium between the transceiver 1230, the processor 1210, and the memory 1220 is not limited in at least one embodiment. In at least one embodiment, the memory 1220, the processor 1210, and the transceiver 1230 are connected through a bus in FIG. 12. The bus is represented by using a thick line in FIG. 12. A manner of a connection between other components is merely an example for description, and is not limited thereto. The bus is classified into an address bus, a data bus, a control bus, and the like. For ease of representation, only one bold line is used to indicate the bus in FIG. 12, but this does not mean that there is only one bus or only one type of bus. In at least one embodiment, the processor is a general-purpose processor, a digital signal processor, an application-specific integrated circuit, a field programmable gate array or another programmable logic device, a discrete gate or transistor logic device, or a discrete hardware component, and implements or perform the methods, steps, and logical block diagrams disclosed in at least one embodiment. The general-purpose processor is a microprocessor or any conventional processor or the like. The steps of the method disclosed with reference to at least one embodiment are directly performed by a hardware processor, or is performed by using a combination of hardware in the processor and a software module.

In at least one embodiment, the memory is a nonvolatile memory, a hard disk drive (HDD) or a solid-state drive (SSD), or is a volatile memory, for example, a random access memory (RAM). The memory is alternatively any other medium that is configured to carry or store expected program code in a form of instructions or a data structure and that is accessed by a computer. This is not limited thereto. The memory in at least one embodiment is alternatively a circuit or any other apparatus that implements a storage function, and is configured to store the computer program, the program instruction, and/or the data.

Based on the foregoing embodiments, refer to FIG. 13. At least one embodiment further provides another communication apparatus 1300, including an interface circuit 1310 and a logic circuit 1320. The interface circuit 1310 is understood as an input/output interface, and is configured to perform operation steps the same as those of the input/output unit shown in FIG. 11 or the transceiver shown in FIG. 12. Details are not described herein again in at least one embodiment. The logic circuit 1320 is configured to run code instructions to perform the method in any one of the foregoing embodiments, is understood as the processing unit in FIG. 11 or the processor in FIG. 12, and implements a same function as the processing unit or the processor. Details are not described herein again in at least one embodiment.

Based on the foregoing embodiments, at least one embodiment further provides a readable storage medium. The readable storage medium stores instructions. In response to the instructions being executed, the encoding method and the decoding method in any one of the foregoing embodiments are implemented. The readable storage medium includes any medium that stores program code, such as a USB flash drive, a removable hard disk, a read-only memory, a random access memory, a magnetic disk, or a compact disc.

A person skilled in the art should understand that at least one embodiment is provided as a method, a system, or a computer program product. Therefore, this application uses a form of hardware only embodiments, software only embodiments, or embodiments with a combination of software and hardware. In addition, this application uses a form of a computer program product that is implemented on one or more computer-usable storage media (including but not limited to a disk memory, a CD-ROM, an optical memory, and the like) that include computer-usable program code.

At least one embodiment is described with reference to the flowcharts and/or block diagrams of the method, the apparatus (system), and the computer program product according to at least one embodiment. Computer program instructions are used to implement each process and/or each block in the flowcharts and/or the block diagrams and a combination of a process and/or a block in the flowcharts and/or the block diagrams. These computer program instructions are provided to a general-purpose computer, a dedicated computer, an embedded processor, or a processor of another programmable data processing apparatus to generate a machine, so that the instructions executed by the computer or the processor of the another programmable data processing apparatus generate an apparatus for implementing a function specified in one or more processes in the flowcharts and/or in one or more blocks in the block diagrams.

These computer program instructions are alternatively stored in a computer-readable memory that instructs a computer or another programmable data processing apparatus to work in a specific manner, so that the instructions stored in the computer-readable memory generate an artifact that includes an instruction apparatus. The instruction apparatus implements a function specified in one or more processes in the flowcharts and/or in one or more blocks in the block diagrams.

These computer program instructions are alternatively loaded onto a computer or another programmable data processing apparatus, so that a series of operations and steps are performed on the computer or the another programmable apparatus, to generate computer-implemented processing. Therefore, the instructions executed on the computer or the another programmable apparatus provide steps for implementing a function specified in one or more processes in the flowcharts and/or in one or more blocks in the block diagrams.

1. An encoding method, comprising:
obtaining an information bit sequence, wherein a length of the information bit sequence is K, and K is a positive integer;
determining a length K1 of a first sequence based on K or M, wherein M is a quantity of modulation symbols, and K1 and M are positive integers;
obtaining a first vector based on K, K1, and a predefined sequence, wherein a length of the first vector is 2JM, M is the quantity of modulation symbols, J is a modulation order, M and J are positive integers, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block;
determining frozen bit locations in the first-type sub-block and information bit locations in the second-type sub-block; and
encoding the information bit sequence based on the frozen bit locations in the first-type sub-block, the information bit locations in the second-type sub-block, and the first vector.

2. The method according to claim 1, wherein the obtaining the first vector based on K, K1, and the predefined sequence includes:
determining a first index set Θ based on K, K1, and the predefined sequence; and
obtaining the first vector based on the first index set Θ, wherein a location index i in the first vector satisfies:
in response to i∈Θ, the location index i carries a first preset value; and
in response to i∉Θ, the location index i carries a second preset value, wherein the first preset value is different from the second preset value, 1≤i≤2JM, and i is a positive integer.

3. The method according to claim 1, wherein an element carried at a (2M(y−1)+1)^{th} location in the first vector to an element carried at a (2My)^{th} location in the first vector correspond to a y^{th} coding sub-block, 1≤y≤J, and y is a positive integer.

4. The method according to claim 1, further comprising:
selecting F information bit locations from the information bit locations in the second-type sub-block, wherein F is a length of frozen bits in the first-type sub-block, and F is an integer; and
assigning values of the F frozen bit locations in the first-type sub-block to the F information bit locations in the second-type sub-block.

5. The method according to claim 1, wherein the encoding the information bit sequence based on the frozen bit locations in the first-type sub-block, the information bit locations in the second-type sub-block, and the first vector further includes:
performing shaping mapping and polar transform on the first sequence to obtain a third sequence;
extracting a fourth sequence from the third sequence based on the first vector, wherein an element in the fourth sequence is a value of an information bit location in the first-type sub-block, and a length of the fourth sequence is less than a length of the third sequence;
performing cyclic redundancy check (CRC) calculation on a fifth sequence to obtain a sixth sequence, wherein the fifth sequence includes a second sequence and the fourth sequence; and
encoding the sixth sequence and the second sequence.

6. The method according to claim 1, wherein the determining the length K1 of a first sequence based on K or M includes determining K1 in the following manner:
manner 1:
determining K1 based on an index value corresponding to K or M; or
manner 2:
determining K1 by using the following formula:
$$K 1 = ⌊ {log}_{2} {C}_{2 M}^{⌊ 2 {Mp}_{bias} ⌋} ⌋ ,$$
wherein
K1 represents the length of the first sequence, M represents the quantity of modulation symbols, and p_{bias} represents a preset shaping probability.

7. The method according to claim 2, wherein the determining the first index set Θ based on K, K1, and the predefined sequence includes:
determining a first parameter T based on K and K1; and
selecting T sequence elements from the predefined sequence to construct the first index set Θ.

8. The method according to claim 7, wherein the determining the first parameter T includes determining the first parameter T in the following manner:
manner 1:
$$T = 2 M + K - K 1 ,$$
wherein
T represents the first parameter, M represents the quantity of modulation symbols, K represents the length of the information bit sequence, and K1 represents the length of the first sequence; or
manner 2:
the first parameter is further related to a CRC length, and T is determined by using the following formula:
$$T = 2 M + K + L - K 1 ,$$
wherein
T represents the first parameter, M represents the quantity of modulation symbols, K represents the length of the information bit sequence, K1 represents the length of the first sequence, and L represents the CRC length.

9. The method according to claim 7, wherein the selecting T sequence elements from the predefined sequence to construct the first index set includes:
selecting T sequence elements from the predefined sequence as the first index set according to a first rule, wherein the first rule includes one of the following: selecting T sequence elements forward from the last sequence element of the predefined sequence as the first index set, and selecting T sequence elements backward from the 1^{st} sequence element of the predefined sequence as the first index set.

10. The method according to claim 2, wherein the first preset value is 1, and the second preset value is 0; or the first preset value is 0, and the second preset value is 1.

11. A decoding method, comprising:
obtaining a to-be-decoded sequence;
determining K and M, wherein K is a length of an information bit sequence, and M is a quantity of modulation symbols;
determining K1 based on K or M, wherein K, K1, and M are positive integers;
obtaining a first vector based on K, K1, and a predefined sequence, wherein a length of the first vector is 2JM, J is a modulation order, J is a positive integer, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block;
determining frozen bit locations in the first-type sub-block and information bit locations in the second-type sub-block; and
decoding the to-be-decoded sequence based on the frozen bit locations in the first-type sub-block, the information bit locations in the second-type sub-block, and the first vector, to obtain the information bit sequence whose length is K.

12. The method according to claim 11, wherein the obtaining the first vector based on K, K1, and the predefined sequence includes:
determining a first index set Θ based on K, K1, and the predefined sequence; and
obtaining the first vector based on the first index set Θ, wherein a location index i in the first vector satisfies:
in response to i∈Θ, the location index i carries a first preset value; and
in response to i∉Θ, the location index i carries a second preset value, wherein the first preset value is different from the second preset value, 1≤i≤2JM, and i is a positive integer.

13. The method according to claim 11, wherein an element carried at a (2M(y−1)+1)^{th} location in the first vector to an element carried at a (2My)^{th} location in the first vector correspond to a y^{th} coding sub-block, 1≤y≤J, and y is a positive integer.

14. The method according to claim 11, further comprising:
selecting F information bit locations from the information bit locations in the second-type sub-block, wherein F is a length of frozen bits in the first-type sub-block, and F is an integer; and
assigning values of the F frozen bit locations in the first-type sub-block to the F information bit locations in the second-type sub-block.

15. The method according to claim 11, wherein the determining K1 based on K or M includes determining K1 in the following manner:
manner 1:
determining K1 based on an index value corresponding to K or M; or
manner 2:
determining K1 by using the following formula:
$$K 1 = ⌊ {log}_{2} {C}_{2 M}^{⌊ 2 {Mp}_{bias} ⌋} ⌋ ,$$
wherein
K1 represents a length of a first sequence, M represents the quantity of modulation symbols, and p_{bias} represents a preset shaping probability.

16. The method according to claim 12, wherein the determining the first index set Θ based on K, K1, and the predefined sequence includes:
determining a first parameter T based on K and K1; and
selecting T sequence elements from the predefined sequence to construct the first index set Θ.

17. The method according to claim 16, wherein the determining the first parameter T based on K and K1 includes determining T in the following manner:
manner 1:
$$T = 2 M + K - K 1 ,$$
wherein
T represents the first parameter, M represents the quantity of modulation symbols, K represents the length of the information bit sequence, and K1 represents the length of the first sequence; or
manner 2:
the first parameter is further related to a CRC length, and T is determined by using the following formula:
$$T = 2 M + K + L - K 1 ,$$
wherein
T represents the first parameter, M represents the quantity of modulation symbols, K represents the length of the information bit sequence, K1 represents the length of the first sequence, and L represents the CRC length.

18. The method according to claim 16, wherein the selecting T sequence elements from the predefined sequence to construct the first index set includes:
selecting T sequence elements from the predefined sequence as the first index set according to a first rule, wherein the first rule includes one of the following: selecting T sequence elements forward from the last sequence element of the predefined sequence as the first index set, and selecting T sequence elements backward from the 1^{st} sequence element of the predefined sequence as the first index set.

19. The method according to claim 12, wherein the first preset value is 1, and the second preset value is 0; or the first preset value is 0, and the second preset value is 1.

20. A communication apparatus, comprising:
memory storing a computer program or instructions; and
at least one processor coupled to the memory, wherein the at least one processor is configured to execute the computer program or instructions to perform operations to:
obtain an information bit sequence, wherein a length of the information bit sequence is K, and K is a positive integer; and
determine a length K1 of a first sequence based on K or M, wherein M is a quantity of modulation symbols, and K1 and M are positive integers; obtain a first vector based on K, K1, and a predefined sequence, wherein a length of the first vector is 2JM, M is the quantity of modulation symbols, J is a modulation order, M and J are positive integers, the first vector indicates J coding sub-blocks, the J coding sub-blocks separately belong to a first-type sub-block or a second-type sub-block, the first-type sub-block includes at least one coding sub-block, and the second-type sub-block includes at least one coding sub-block; determine frozen bit locations in the first-type sub-block and information bit locations in the second-type sub-block; and encode the information bit sequence based on the frozen bit locations in the first-type sub-block, the information bit locations in the second-type sub-block, and the first vector.
